(19) United States
(12) Patent Application Publication
(10) Pub. No.: US 2025/0048684 A1
(43) Pub. Date: Feb. 6, 2025

(54) SEMICONDUCTOR DEVICE

(71) Applicant: FUJI ELECTRIC CO., LTD., Kanagawa (JP)

(72) Inventors: Shuntaro YAGUCHI, Matsumoto-city (JP); Takashi YOSHIMURA, Matsumoto-city (JP); Hiroshi TAKISHITA, Matsumoto-city (JP); Yuusuke OOSHIMA, Matsumoto-city (JP); Hidenori TSUJI, Higashimurayama-city (JP)

(21) Appl. No.: 18/924,878

(22) Filed: Oct. 23, 2024

Related U.S. Application Data
(63) Continuation of application No. PCT/JP2023/025510, filed on Jul. 10, 2023.

(30) Foreign Application Priority Data
Nov. 8, 2022 (JP) 2022-179133

(51) Int. Cl. H01L 29/06; H01L 29/66; H01L 29/739

(52) U.S. Cl. CPC H01L 29/0611; H01L 29/66348; H01L 29/7397

(57) ABSTRACT

Provided is a semiconductor device comprising a semiconductor substrate having an upper surface and a lower surface, with a bulk donor distributed between the upper surface and the lower surface, that has a drift region of a first conductivity type provided thereon, the semiconductor device comprising a high-concentration region of a first conductivity type that is arranged between the drift region and the lower surface of the semiconductor substrate, includes a hydrogen donor, and has a carrier concentration that is higher than a bulk donor concentration, wherein the high-concentration region has a first portion in which a hydrogen donor concentration obtained by subtracting a bulk donor concentration from a carrier concentration is 7×10¹³/cm³ or more and 1.5×10¹⁴/cm³ or less, and a length of the first portion in a depth direction of the semiconductor substrate is 50% or more of a length of the high-concentration region.

The contents of the following patent application(s) are incorporated herein by reference:
NO. 2022-179133 filed in JP on Nov. 8, 2022
NO. PCT/JP2023025510 filed in WO on Jul. 10, 2023

### BACKGROUND

### 1. Technical Field

The present invention relates to a semiconductor device.

### 2. Related Art

A semiconductor device in which a donor region with a higher concentration than a bulk donor concentration is formed by implanting hydrogen ion such as proton into a semiconductor substrate to form a hydrogen donor is known (see Patent Documents 1 to 3, for example).
Patent Document 1: WO 2022/107727
Patent Document 2: US2015%214347
Patent Document 3: US2019/0148500

### BRIEF DESCRIPTION OF THE DRAWINGS

FIG. 1 is a top view illustrating an example of a semiconductor device 100 according to one embodiment of the present invention.

FIG. 2 illustrates an enlarged view of a region D in FIG. 1.

FIG. 3 illustrates an example of a cross section e-e in FIG. 2.

FIG. 4 illustrates a reference example of a distribution of each of a hydrogen chemical concentration, a carrier concentration, and a hydrogen donor concentration at line f-f in FIG. 3.

FIG. 5 illustrates an example of a fluctuation in the carrier concentration distribution according to fluctuation in the oxygen concentration and the carbon concentration in the semiconductor substrate 10.

FIG. 6 illustrates an an example of a fluctuation in the hydrogen donor concentration distribution according to fluctuation in the oxygen concentration and the carbon concentration in the semiconductor substrate 10.

FIG. 7 illustrates a ratio relationship of a hydrogen donor increase amount in each concentration distribution to the hydrogen donor concentration in the concentration distribution 310.

FIG. 8 illustrates a distribution of each of the hydrogen chemical concentration, the carrier concentration, and the hydrogen donor concentration at line f-f in FIG. 3, according to one example.

FIG. 9 illustrates an example of the hydrogen donor concentration distribution in a high-concentration region 20.

FIG. 10 illustrates another example of the hydrogen donor concentration distribution in the high-concentration region 20.

FIG. 11 is an enlarged view of a hydrogen chemical concentration peak 202-m.

FIG. 12 illustrates the hydrogen donor concentration distribution.

FIG. 13 illustrates another example of the hydrogen chemical concentration distribution and the hydrogen donor concentration distribution.

FIG. 14 illustrates another example of the hydrogen chemical concentration distribution and the hydrogen donor concentration distribution.

FIG. 15 illustrates an example of a boundary position Zb.

FIG. 16 illustrates another example of the boundary position Zb.

FIG. 17 is a e-e cross sectional view illustrating an example of a semiconductor device 100A according to another embodiment of the present invention.

FIG. 18A illustrates an example of the doping concentration distribution at line g-g in FIG. 17.

FIG. 18B illustrates an example of the chemical concentration distribution of each dopant at line g-g in FIG. 17.

FIG. 19 illustrates the distribution of an antimony chemical concentration in a second depth range 192 of a drift region 18.

FIG. 20A is a flow diagram illustrating a manufacturing method of the semiconductor device 100A.

FIG. 20B illustrates each step of S1010 to S1030 of the manufacturing method of the semiconductor device 100A.

FIG. 20C illustrates each step of S1040 to S1060 of the manufacturing method of the semiconductor device 100A.

FIG. 20D illustrates each step of S1070 to S1090 of the manufacturing method of the semiconductor device 100A.

FIG. 21 illustrates a characteristic of breakdown voltage dispersion in the drift region 18 and the high-concentration region 20.

FIG. 22 is a graph illustrating the ratio relationship of the breakdown voltage dispersion to a coefficient ζ.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of an N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si—H which is a combination of interstitial silicon (Si-i) and hydrogen in a silicon semiconductor also functions as the donor that supplies electrons. Alternatively, CiOi-H which is a combination of interstitial carbon (Ci), interstitial oxygen (Oi), and hydrogen functions as the donor that supplies electrons. In the present specification, the VOH defect, the interstitial Si—H, or CiOi-H may be referred to as the hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in this example is an element other than hydrogen. The bulk donor dopant is, for example, phosphorous, antimony, arsenic, selenium, or sulfur, but the invention is not limited to these. The bulk donor in this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any one of a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration. Note that, the donor concentration of the hydrogen donor may be 0.1% or more and 50% or less of the hydrogen chemical concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

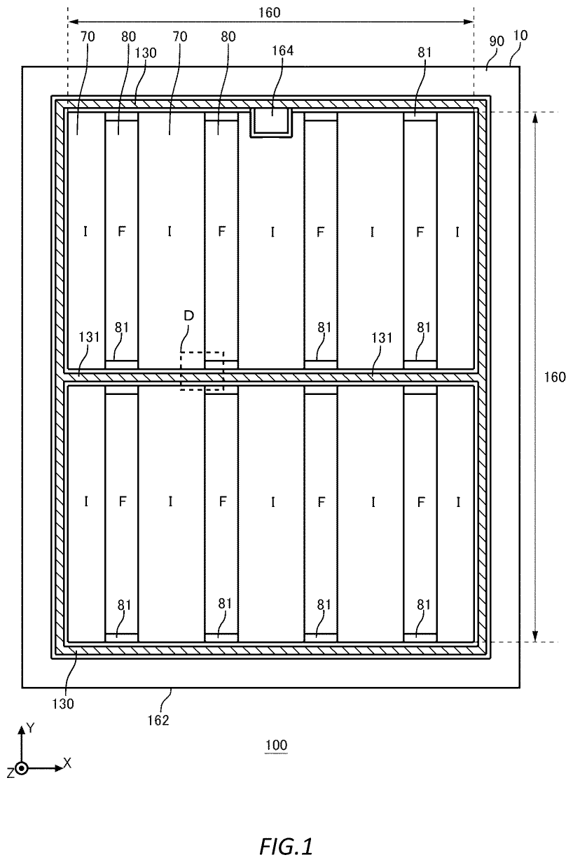

FIG. 1 is a top view illustrating an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in a top view. When simply referred to as a top view in the present specification, it means that the semiconductor substrate 10 is viewed from an upper surface side. The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched between active portions 160 in a top view may also be included in the active portion 160.

The active portion 160 is provided with at least one of a transistor portion 70 including a transistor element such as an insulated gate bipolar transistor (IGBT) and a diode portion 80 including a diode element such as a freewheeling diode (FWD). In the example shown in FIG. 1, the transistor portions 70 and the diode portions 80 are alternately arranged along a predetermined array direction (the X axis direction in this example) at the upper surface of the semiconductor substrate 10. The semiconductor device 100 in this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in a top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is greater than the width in the X axis direction. Similarly, the length of each of the diode portions 80 in the Y axis direction is greater than the width in the X axis direction. The extending direction of the transistor portion 70 and the diode portion 80, and the longitudinal direction of each trench portion described below may be the same.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of a P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. In addition, in the transistor portion 70, an emitter region of an N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 in this example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in a top view. When the semiconductor device 100 is mounted, each pad may be connected to an external circuit through a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in this example encloses the active portion 160 in a top view. A region enclosed by the outer circumferential gate runner 130 in a top view may be defined as the active portion 160. In addition, a well region is formed below the gate runner. The well region is a P type region having a higher concentration than the base region described below, and is formed up to a position deeper than a position of the base region from the upper surface of the semiconductor substrate 10. A region enclosed by the well region in a top view may be the active portion 160.

An outer circumferential gate runner 130 is connected to the gate pad 164. The outer circumferential gate runner 130 is arranged above the semiconductor substrate 10. The outer circumferential gate runner 130 may be a metal wiring including aluminum or the like.

The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runners 130 and the active-side gate runner 131 are connected to the gate trench portion of the active portion 160. The outer circumferential gate runners 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 in this example is provided extending in the X axis direction so as to cross the active portion 160 substantially at the center of the Y axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X axis direction in each divided region.

The semiconductor device 100 may include a temperature sensing portion (not shown) which is a PN junction diode formed of polysilicon or the like, and a current detection portion (not shown) which simulates an operation of a transistor portion provided in the active portion 160.

The semiconductor device 100 in this example includes an edge termination structure portion 90 between the active portion 160 and the end side 162 in a top view. The edge termination structure portion 90 in this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided enclosing the active portion 160.

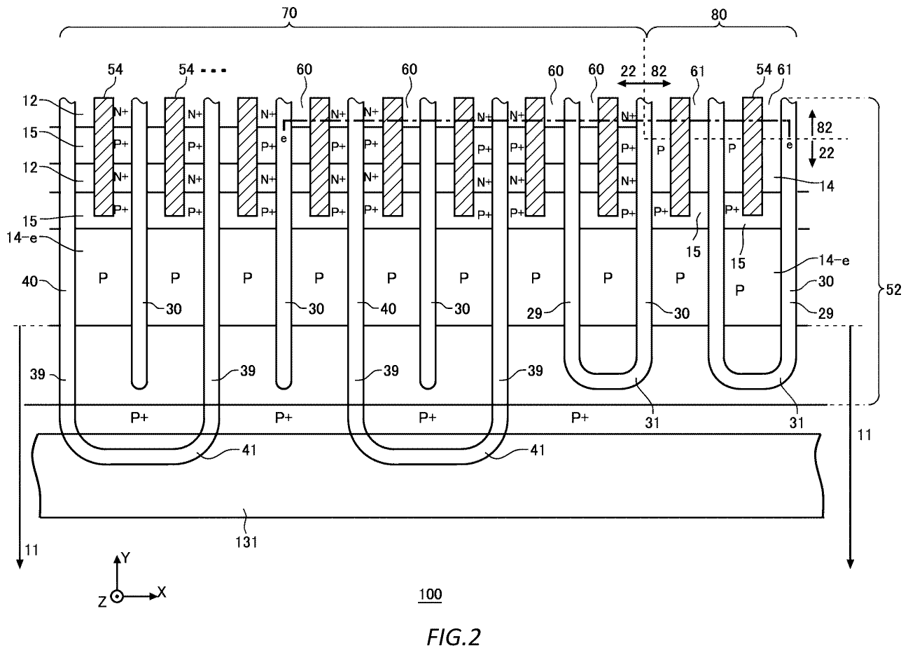

FIG. 2 illustrates an enlarged view of a region D in FIG. 1. The region D is a region including a transistor portion 70, a diode portion 80, and an active-side gate runner 131. A semiconductor device 100 in this example includes gate trench portions 40, dummy trench portions 30, a well region 11, emitter regions 12, base regions 14, and contact regions 15 which are provided inside on an upper surface side of a semiconductor substrate 10. The gate trench portion 40 and the dummy trench portion 30 each are an example of the trench portion. In addition, the semiconductor device 100 in this example includes an emitter electrode 52 and the active-side gate runner 131 that are provided on or above the upper surface of the semiconductor substrate 10. The emitter electrode 52 and the active-side gate runner 131 are provided in isolation from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in this example, a contact hole 54 is provided penetrating the interlayer dielectric film. In FIG. 2, each contact hole 54 is hatched with the diagonal lines.

The emitter electrode 52 is provided above the gate trench portions 40, the dummy trench portions 30, the well region 11, the emitter regions 12, the base regions 14, and the contact regions 15. The emitter electrode 52 is in contact with the emitter regions 12, the contact regions 15, and the base regions 14 at the upper surface of the semiconductor substrate 10, through the contact holes 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in a contact hole.

The well region 11 is provided overlapping the active-side gate runner 131. The well region 11 is provided so as to extend with a predetermined width even in a range not overlapping the active-side gate runner 131. The well region 11 in this example is provided away from an end of the contact hole 54 in the Y axis direction toward the active-side gate runner 131 side. The well region 11 is a region of a second conductivity type having a higher doping concentration than the base region 14. The base region 14 of this example is a P− type, and the well region 11 is a P+ type.

Each of the transistor portion 70 and the diode portion 80 has a plurality of trench portions arrayed in an array direction. In the transistor portion 70 in this example, one or more gate trench portions 40 and one or more dummy trench portions 30 are alternately provided along the array direction. In the diode portion 80 in this example, the plurality of dummy trench portions 30 are provided along the array direction. In the diode portion 80 in this example, the gate trench portion 40 is not provided.

The gate trench portion 40 in this example may include two linear portions 39 extending along an extending direction perpendicular to the array direction (trench portions which are linear along the extending direction), and the edge portion 41 connecting the two linear portions 39. The extending direction in FIG. 2 is the Y axis direction.

At least a part of the edge portion 41 is preferably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom portion in a depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion in this example is provided extending in the extending direction (the Y axis direction) along the trench, at the upper surface of the semiconductor substrate 10. In this example, mesa portions 60 are provided in the transistor portion 70, and mesa portions 61 are provided in the diode portion 80. In a case of simply mentioning “mesa portion” in the present specification, the portion refers to each of a mesa portion 60 and a mesa portion 61.

Each of the mesa portions is provided with base regions 14. In the mesa portion, a region arranged closest to the active-side gate runner 131 among the base regions 14 exposed on the upper surface of the semiconductor substrate 10 is defined as a base region 14-e. While FIG. 2 shows a base region 14-e arranged at one end portion of each of the mesa portions in the extending direction, a base region 14-e is arranged also at another end portion of each of the mesa portions. Each of the mesa portions may be provided with at least one of an emitter region 12 of a first conductivity type or a contact region 15 of the second conductivity type in a region sandwiched between base regions 14-e in a top view. The emitter region 12 in this example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 includes the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact regions 15 and the emitter regions 12 in the mesa portion 60 are alternately arranged along the extending direction of the trench portion (the Y axis direction).

In another example, the contact regions 15 and the emitter regions 12 of the mesa portion 60 may be provided in a striped pattern along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 at the upper surface of the mesa portion 61. The base region 14 may be arranged throughout the region sandwiched between the contact regions 15.

The contact hole 54 is provided above each mesa portion. The contact hole 54 is arranged in the region sandwiched between the base regions 14-e. The contact hole 54 in this example is provided above each of the contact regions 15, the base region 14, and the emitter regions 12. The contact hole 54 is not provided in regions corresponding to the base region 14-e and the well region 11. The contact hole 54 may be arranged at a center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and the collector region 22 are provided between the lower surface 23 of the semiconductor substrate 10 and the high-concentration region 20. In FIG. 2, a boundary between the cathode region 82 and the collector region 22 is indicated by a dotted line.

The cathode region 82 is arranged away from the well region 11 in the Y axis direction. With this configuration, the distance between a region of a P type (the well region 11) having a comparatively high doping concentration and formed up to the deep position, and the cathode region 82 is ensured, so that the breakdown voltage can be improved. The end portion in the Y axis direction of the cathode region 82 in this example is arranged farther away from the well region 11 than the end portion in the Y axis direction of the contact hole 54. In another example, the end portion in the Y axis direction of the cathode region 82 may be arranged between the well region 11 and the contact hole 54.

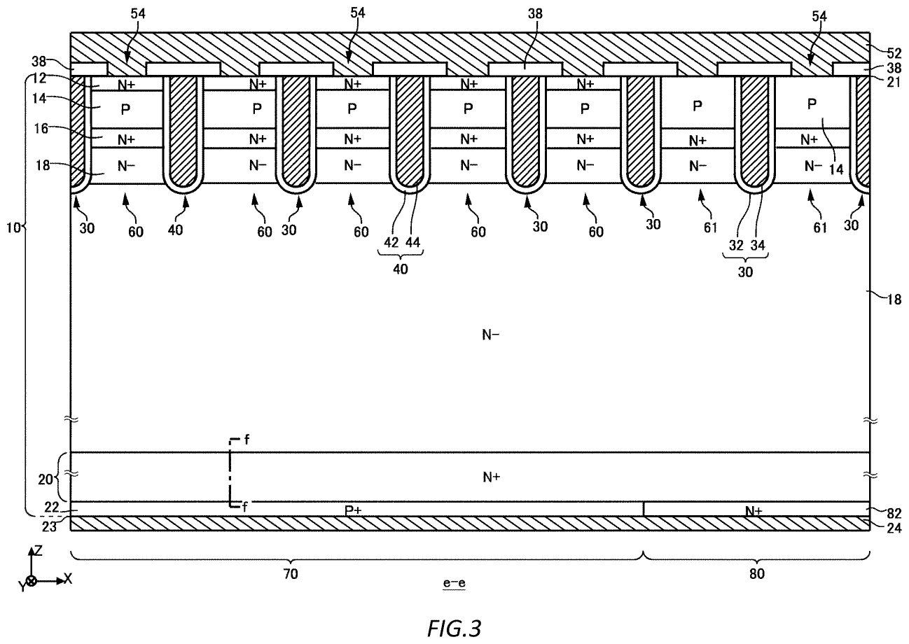

FIG. 3 illustrates an example of a cross section e-e in FIG. 2. The cross section e-e is the XZ plane passing through an emitter region 12 and a cathode region 82. A semiconductor device 100 in this example includes a semiconductor substrate 10, an interlayer dielectric film 38, an emitter electrode 52, and a collector electrode 24 in the cross section.

The interlayer dielectric film 38 is provided on an upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with a contact hole 54 described with reference to FIG. 2.

The emitter electrode 52 is provided above the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as a depth direction.

The semiconductor substrate 10 includes a drift region 18 of an N type or an N− type. The drift region 18 is provided in each of a transistor portion 70 and a diode portion 80.

In the mesa portion 60 of the transistor portion 70, an N+ type of emitter region 12 and a P− type of base region 14 are provided in order from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed on the upper surface 21 of the semiconductor substrate 10 and is provided in contact with a gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the mesa portion 60.

The accumulation region 16 is provided below the base region 14. The accumulation region 16 is a region of the N+ type having a higher doping concentration than the drift region 18. That is, the accumulation region 16 has a higher donor concentration than the drift region 18. Providing the accumulation region 16 having a high concentration between the drift region 18 and the base region 14 can increase a carrier implantation enhancement effect (IE effect) and reduce an on-voltage. The accumulation region 16 may be provided so as to cover the entire lower surface of the base region 14 in each mesa portion 60.

The mesa portion 61 of the diode portion 80 is provided with the P− type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, a high-concentration region 20 of an N+ type may be provided below the drift region 18. The doping concentration of the high-concentration region 20 is higher than the doping concentration of the drift region 18. The high-concentration region 20 may have a concentration peak with a higher doping concentration than the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The high-concentration region 20 may have two or more concentration peaks in a depth direction (Z axis direction) of the semiconductor substrate 10. The concentration peak of the high-concentration region 20 may be provided at a same depth position as the chemical concentration peak of hydrogen (proton) or phosphorous, for example. The high-concentration region 20 may function as a field stopper layer to prevent a depletion layer, which expands from the lower end of the base region 14, from reaching the P+ type collector region 22 and the N+ type cathode region 82.

In the transistor portion 70, the P+ type collector region 22 is provided under the high-concentration region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

In diode portion 80 the N+ type cathode region 82 is provided under the high-concentration region 20. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each of the trench portions is provided from the upper surface 21 of the semiconductor substrate 10 penetrating the base region 14 to below the base region 14. In a region where at least any of the emitter region 12, the contact region 15, and the accumulation region 16 is provided, each trench portion also penetrates the doping regions of these. The configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions.

As described above, the transistor portion 70 is provided with the gate trench portion 40 and a dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided covering the inner wall of the gate trench. The gate dielectric film 42 may be formed by oxidizing or nitriding a semiconductor on the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in this example are covered with the interlayer dielectric film 38 on the upper surface 21 of the semiconductor substrate 10. Note that the bottom portions of the dummy trench portion 30 and the gate trench portion 40 may be formed in a curved-surface shape (a curved shape in the cross section) convexly downward.

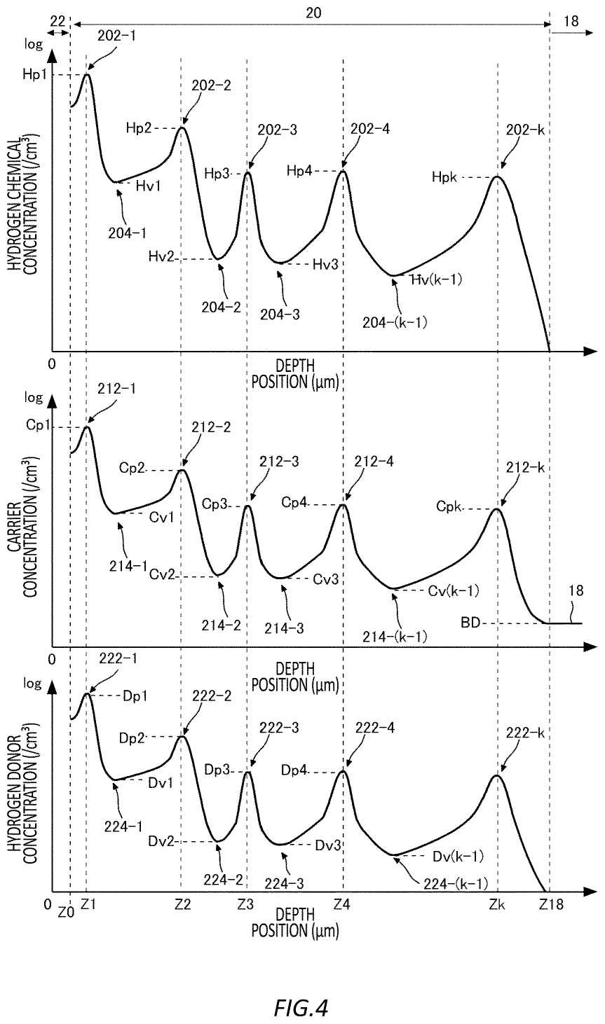

FIG. 4 illustrates a reference example of a distribution of each of a hydrogen chemical concentration, a carrier concentration, and a hydrogen donor concentration at line f-f in FIG. 3. The line f-f is a line parallel to the Z axis that passes through the high-concentration region 20. A horizontal axis in FIG. 4 represents a depth position (a position in the Z axis direction) in the semiconductor substrate 10. In the present specification, except for a case particularly described, the distance from the lower surface 23 is defined as a position in the Z axis direction, with the lower surface 23 of the semiconductor substrate 10 as the reference position in the Z axis direction.

The drift region 18 is provided above the high-concentration region 20. The doping concentration of the drift region 18 may be substantially constant. The doping concentration of the drift region 18 may be identical to a bulk donor concentration BD. The bulk donor concentration BD is a chemical concentration of the bulk donor that is distributed throughout the entire area between the upper surface 21 and the lower surface 23 of the semiconductor substrate 10. As the bulk donor concentration BD, a minimum value of the chemical concentration of the bulk donor at the semiconductor substrate 10 may be used, a chemical concentration of the bulk donor at a center position in the depth direction of the semiconductor substrate 10 may be used, or an average value of a chemical concentration of the bulk donor at the drift region 18 may be used. A depth position at the boundary between the drift region 18 and the high-concentration region 20 is defined as Z18. The depth position Z18 is a depth position where the doping concentration becomes BD for the first time in a direction from the high-concentration region 20 toward the drift region 18.

The high-concentration region 20 is provided between the drift region 18 and the lower surface 23. The collector region 22 is provided between the high-concentration region 20 and the lower surface 23. In FIG. 4, the hydrogen chemical concentration, the carrier concentration, and the hydrogen donor concentration in the collector region 22 is omitted. A boundary position Z0 between the collector region 22 and the high-concentration region 20 is a position of a PN-junction between the collector region 22 and the high-concentration region 20.

The high-concentration region 20 is a region including the hydrogen donor. In the present specification, an N type region between the drift region 18 and the collector region 22 in which hydrogen atoms exist and the carrier concentration is higher than the bulk donor concentration BD is defined as the high-concentration region 20.

The high-concentration region 20 has a plurality of hydrogen chemical concentration peaks 202 in the depth direction. In the example of FIG. 4, a hydrogen chemical concentration peak 202-1, a hydrogen chemical concentration peak 202-2, a hydrogen chemical concentration peak 202-3, a hydrogen chemical concentration peak 202-4 . . . , hydrogen chemical concentration peak 202-k are arranged in the high-concentration region 20, in an order from the peak closest to the lower surface 23 of the semiconductor substrate 10. Here, k is an integer of 2 or more. In the present specification, the hydrogen chemical concentration peak 202-1 may be referred to as a shallowest hydrogen peak, and the hydrogen chemical concentration peak 202-k may be referred to as a deepest hydrogen peak. A maximum value of a hydrogen chemical concentration of a hydrogen chemical concentration peak 202-m (m is an integer from 1 to k) is defined as Hpm. That is, the hydrogen chemical concentration at a local maximum of the hydrogen chemical concentration peak 202-m is defined as Hpm. The depth position Zm of the local maximum of the hydrogen chemical concentration peak 202-m is defined as the depth position of each hydrogen chemical concentration peak 202-m.

In each example of the present specification, a range that spans from an upper end of the collector region 22 to a lower end of the drift region 18 is defined as the high-concentration region 20. In each example of the present specification, an area from a position Z1 of the local maximum of the shallowest hydrogen peak (hydrogen chemical concentration peak 202-1) to a position Zk of the local maximum of the deepest hydrogen peak (hydrogen chemical concentration peak 202-k) may be defined as the high-concentration region 20.

A hydrogen chemical concentration valley portion 204 is provided between two hydrogen chemical concentration peaks 202 that are adjacent to each other in the depth direction. In the high-concentration region 20, one or more of the hydrogen chemical concentration valley portions 204 are arranged in the depth direction. In the example of FIG. 4, the hydrogen chemical concentration valley portion 204-1, the hydrogen chemical concentration valley portion 204-2, the hydrogen chemical concentration valley portion 204-3, . . . , the hydrogen chemical concentration valley portion 204-(k−1) are arranged in the high-concentration region 20 in an order from the valley portion closest to the lower surface 23 of the semiconductor substrate 10. Here, k is an integer of 1 or more. In the present specification, the hydrogen chemical concentration valley portion 204-1 may be referred to as a shallowest hydrogen valley portion, and the hydrogen chemical concentration valley portion 204-(k−1) may be referred to as a deepest hydrogen valley portion. A minimum value of a hydrogen chemical concentration of the hydrogen chemical concentration valley portion 204-m (m is an integer from 1 to k−1) is defined as Hvm. That is, the hydrogen chemical concentration at a bottom portion of the hydrogen chemical concentration valley portion 204-m is defined as Hvm.

The high-concentration region 20 has a plurality of carrier concentration peaks 212 in the depth direction. In the example of FIG. 4, a carrier concentration peak 212-1, a carrier concentration peak 212-2, a carrier concentration peak 212-3, a carrier concentration peak 212-4, . . . a carrier concentration peak 212-k are arranged in the high-concentration region 20 in an order from the peak closest to the lower surface 23 of the semiconductor substrate 10. Here, k is an integer of 2 or more. In the present specification, the carrier concentration peak 212-1 may be referred to as a shallowest carrier peak, and the carrier concentration peak 212-k may be referred to as a deepest carrier peak. A maximum value of a carrier concentration of a carrier concentration peak 212-m (m is an integer from 1 to k) is defined as Cpm. That is, the carrier concentration at a local maximum of the carrier concentration peak 212-m is defined as Cpm. The carrier concentration peak 212-m is arranged at a same depth position Zm as the hydrogen chemical concentration peak 202-m. The carrier concentration peak 212-m may be defined as being arranged at the depth position Zm as long as the depth position Zm is included within full width at half maximum in the depth direction of the carrier concentration peak 212-m. The local maximum of the carrier concentration peak 212-m may be arranged at the depth position Zm.

A carrier concentration valley portion 214 is provided between two carrier concentration peaks 212 that are adjacent to each other in the depth direction. In the high-concentration region 20, one or more of the carrier concentration valley portions 214 are arranged in the depth direction. In the example of FIG. 4, a carrier concentration valley portion 214-1, a carrier concentration valley portion 214-2, a carrier concentration valley portion 214-3, . . . , a carrier concentration valley portion 214-(k−1) are arranged in the high-concentration region 20 in an order from the valley portion closest to the lower surface 23 of the semiconductor substrate 10. Here, k is an integer of 1 or more. In the present specification, the carrier concentration valley portion 214-1 may be referred to as a shallowest carrier concentration valley portion, and the carrier concentration valley portion 214-(k−1) may be referred to as a deepest carrier concentration valley portion. A minimum value of a carrier concentration of a carrier concentration valley portion 214-m (m is an integer from 1 to k−1) is defined as Cvm. That is, the carrier concentration at the bottom portion of the carrier concentration valley portion 214-m is defined as Cvm.

At respective depth positions of the high-concentration regions 20, the concentration obtained by subtracting the bulk donor concentration BD from the carrier concentration is defined as the hydrogen donor concentration. The high-concentration region 20 has a plurality of hydrogen donor concentration peaks 222 in the depth direction. In the example of FIG. 4, a hydrogen donor concentration peak 222-1, a hydrogen donor concentration peak 222-2, a hydrogen donor concentration peak 222-3, a hydrogen donor concentration peak 222-4, . . . , a hydrogen donor concentration peak 222-k are arranged in the high-concentration region 20 in an order from the peak closest to the lower surface 23 of the semiconductor substrate 10. Here, k is an integer of 2 or more. In the present specification, the hydrogen donor concentration peak 222-1 may be referred to as a shallowest hydrogen donor concentration peak, and the hydrogen donor concentration peak 222-k may be referred to as a deepest hydrogen donor concentration peak. A maximum value of a hydrogen donor concentration of a hydrogen donor concentration peak 222-m (m is an integer from 1 to k) is defined as Dpm. That is, the hydrogen donor concentration at the local maximum of the hydrogen donor concentration peak 222-m is defined as Dpm. The hydrogen donor concentration peak 222-m is arranged at a same depth position Zm as the carrier concentration peak 212-m.

A hydrogen donor concentration valley portion 224 is provided between two hydrogen donor concentration peaks 222 that are adjacent to each other in the depth direction. In the high-concentration region 20, one or more of the hydrogen donor concentration valley portions 224 are arranged in the depth direction. In the example of FIG. 4, a hydrogen donor concentration valley portion 224-1, a hydrogen donor concentration valley portion 224-2, a hydrogen donor concentration valley portion 224-3, . . . , a hydrogen donor concentration valley portion 224-(k−1) are arranged in the high-concentration region 20 in an order from the valley portion closest to the lower surface 23 of the semiconductor substrate 10. Here, k is an integer of 1 or more. In the present specification, the hydrogen donor concentration valley portion 224-1 may be referred to as a shallowest hydrogen donor concentration valley portion, and the hydrogen donor concentration valley portion 224-(k−1) may be referred to as a deepest hydrogen donor concentration valley portion. A minimum value of a hydrogen donor concentration of a hydrogen donor concentration valley portion 224-m (m is an integer from 1 to k−1) is defined as Dvm. That is, the hydrogen donor concentration at the bottom portion of the hydrogen donor concentration valley portion 224-m is defined as Dvm.

The hydrogen donor concentration (/cm³) can be adjusted by a dose amount (/cm²) of hydrogen ions such as proton to be implanted into the semiconductor substrate 10. For example, the hydrogen donor concentration can be increased by increasing the dose amount of the hydrogen ions. On the other hand, even when the dose amount of the hydrogen ions is constant, the extent of the hydrogen ions becoming a donor is fluctuated according to the oxygen concentration and the carbon concentration in the semiconductor substrate 10, which causes the hydrogen donor concentration to be fluctuated. That is, the donor concentration is fluctuated. Thus, the carrier concentration in the high-concentration region 20 is fluctuated according to the oxygen concentration and the carbon concentration in the semiconductor substrate 10. When the carrier concentration in the high-concentration region 20 is fluctuated, characteristics such as the breakdown voltage of the semiconductor device 100 is fluctuated.

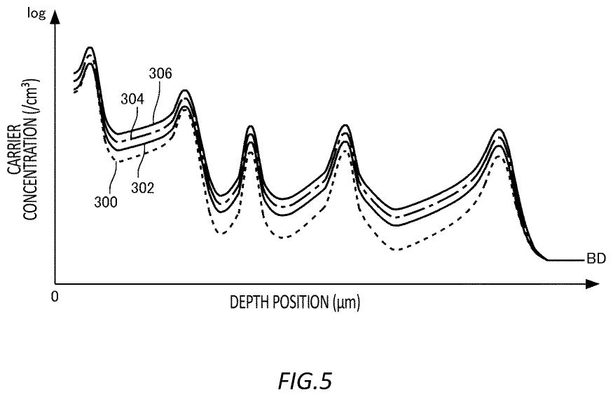

FIG. 5 illustrates an example of a fluctuation in the carrier concentration distribution according to fluctuation in the oxygen concentration and the carbon concentration in the semiconductor substrate 10. The concentration distribution 300 indicates the carrier concentration distribution in the high-concentration region 20 in a case where hydrogen ions are dosed into a semiconductor substrate 10 having sufficiently low oxygen concentration and carbon concentration and the semiconductor substrate 10 is subjected to heat treatment, such that hydrogen chemical concentration distribution as illustrated in FIG. 4 is achieved. The semiconductor substrate 10 in the concentration distribution 300 is a substrate formed by FZ method, for example, and has a oxygen concentration of 1×10¹⁶/cm³ or less and a carbon concentration of 1×10¹⁵/cm³ or less.

Other concentration distributions 302, 304. 306 each indicate a carrier concentration distribution in the high-concentration region 20 in a case where a high-concentration region 20 is formed with the same dosing condition and heat treatment condition as the concentration distribution 300 in a semiconductor substrate 10 with a oxygen concentration and a carbon concentration that are different from those of the concentration distribution 300. The oxygen concentration and the carbon concentration in the semiconductor substrate 10 increases in the order of the concentration distribution 300, the concentration distribution 302, the concentration distribution 304, the concentration distribution 306. The semiconductor substrate 10 in the concentration distribution 302 has a oxygen concentration of 3×10¹⁷/cm³ or less and a carbon concentration of 3×10¹⁶/cm³ or less. The semiconductor substrate 10 in the concentration distribution 304 has a oxygen concentration of 3×10¹⁷/cm³ to 5×10¹⁷/cm³ and a carbon concentration of 3×10¹⁶/cm³ to 5×10¹⁶/cm³. The semiconductor substrate 10 in the concentration distribution 306 has a oxygen concentration of 5×10¹⁷/cm³ or more and a carbon concentration of 5×10¹⁶/cm³ or more.

As illustrated in FIG. 5, the higher the oxygen concentration and the carbon concentration of the semiconductor substrate 10, the higher the carrier concentration tends to be. Thus, when the oxygen concentration and the carbon concentration of the semiconductor substrate 10 are varied, the carrier concentration in the high-concentration region 20 is also varied. This is considered to be because the extent of the hydrogen donor being formed changes according to the oxygen concentration and the carbon concentration in the semiconductor substrate 10.

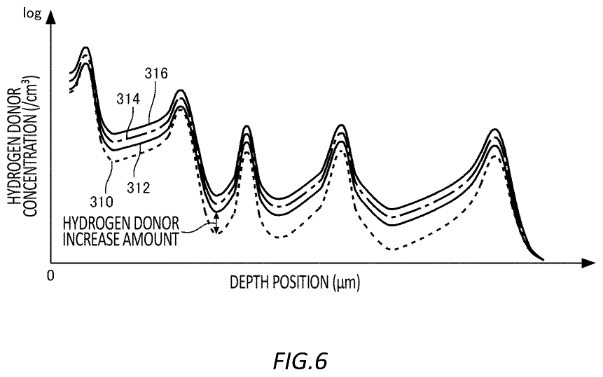

FIG. 6 illustrates an example of a fluctuation in the hydrogen donor concentration distribution according to fluctuation in the oxygen concentration and the carbon concentration in the semiconductor substrate 10. As described above, the hydrogen donor concentration in the present specification is a concentration obtained by subtracting the bulk donor concentration BD from the carrier concentration. The concentration distribution 310, the concentration distribution 312, the concentration distribution 314, and the concentration distribution 316 correspond to the concentration distribution 300, the concentration distribution 302, the concentration distribution 304, and the concentration distribution 306 in FIG. 5, respectively.

The increase amount of the hydrogen donor concentration in each concentration distribution when the hydrogen donor concentration in the concentration distribution 310 is defined as a reference is defined as a hydrogen donor increase amount. Although, in FIG. 6, a hydrogen donor increase amount in the concentration distribution 312 at a certain depth position is illustrated with an arrow, the hydrogen donor increase amount can be calculated for all depth positions and all concentration distributions. As illustrated in FIG. 6, when the oxygen concentration and the carbon concentration in the semiconductor substrate 10 are fluctuated, the hydrogen donor increase amount is also fluctuated.

As illustrated in FIG. 6, the lower the hydrogen donor concentration in the concentration distribution 310, the larger the fluctuation in the hydrogen donor increase amount in another concentration distribution at the same depth position tends to be. In addition, the fluctuation in the hydrogen donor increase amount in each concentration distribution is small in the vicinity of the peaks of the concentration distribution 310, and the fluctuation in the hydrogen donor increase amount in each concentration distribution is large in the vicinity of the valley portions. Thus, in the high-concentration region 20, variation in the hydrogen donor increase amount in the high-concentration region 20 can be suppressed and variation in the carrier concentration can be suppressed by performing at least one of reducing a region with a low hydrogen donor concentration or increasing a pulse density in the high-concentration region 20 (the depth ratio of the peak region of the hydrogen donor in the high-concentration region 20).

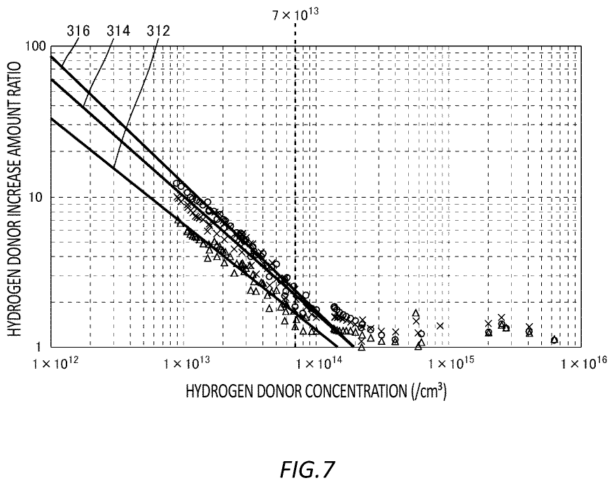

FIG. 7 illustrates a ratio relationship of a hydrogen donor increase amount in each concentration distribution to the hydrogen donor concentration in the concentration distribution 310. The horizontal axis in FIG. 7 indicates the hydrogen donor concentration in the concentration distribution 310. The vertical axis in FIG. 7 indicates the hydrogen donor increase amount ratio obtained by dividing the hydrogen donor increase amount at respective depth positions in concentration distributions 312, 314, 316 (see FIG. 6) by the hydrogen donor concentration in the concentration distribution 310 at the same depth position. The circle plots in FIG. 7 correspond to the concentration distribution 316, the x plots correspond to the concentration distribution 314, and the triangle plots correspond to the concentration distribution 312. In this example, the hydrogen donor increase amount ratio in each concentration distribution was calculated at a plurality of depth positions, with the characteristics illustrated in FIG. 6. Respective hydrogen donor increase amount ratios were plotted with the corresponding hydrogen donor concentration in the concentration distribution 310 as the horizontal axis to create the graph in FIG. 7. In FIG. 7, the distribution of each plot corresponding to the concentration distributions 312, 314, and 316 is approximated with a straight line.

As illustrated in FIG. 7, when the hydrogen donor concentration in the horizontal axis becomes 7×10¹³/cm³ or more, the variation in the hydrogen donor increase amount ratio is mostly settled. When the hydrogen donor concentration in the horizontal axis becomes 1×10¹⁴/cm³ or more, the hydrogen donor increase amount ratio becomes mostly constant at approximately 1 to 1.6, regardless of the oxygen concentration and the carbon concentration in the semiconductor substrate 10. On the other hand, in a region where the hydrogen donor concentration in the horizontal axis is less than 7×10¹³/cm³, the smaller the hydrogen donor concentration, hydrogen donor increase amount ratio in each concentration distribution is increased and the variation among the concentration distributions is also increased. Thus, in a region where the hydrogen donor concentration in the horizontal axis is less than 7×10¹³/cm³, the smaller the hydrogen donor concentration, the variation in the hydrogen donor increase amount ratio due to the oxygen concentration and the carbon concentration in the semiconductor substrate 10 is also increased.

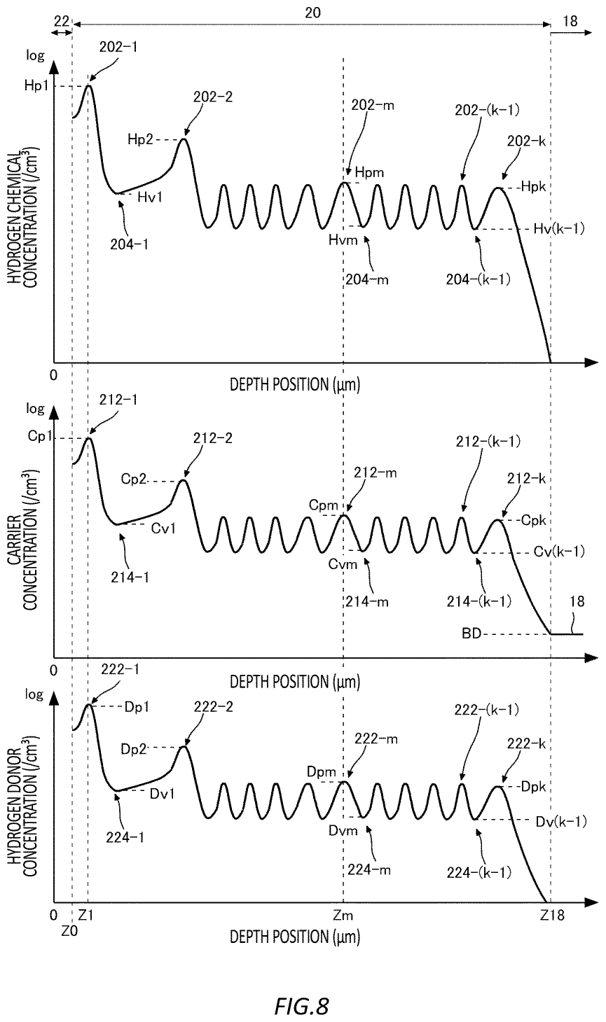

FIG. 8 illustrates a distribution of each of the hydrogen chemical concentration, the carrier concentration, and the hydrogen donor concentration at line f-f in FIG. 3, according to one example. In FIG. 8, similar reference numerals as those in the example described in FIG. 4 are used. Note that, the m^{th} (m is an integer from 1 to k) peak, among the plurality of hydrogen chemical concentration peaks 202, counted from the lower surface 23 of the semiconductor substrate 10 is defined as the hydrogen chemical concentration peak 202-m. In addition, the m^{th} (m is an integer from 1 to k−1) valley portion, among the plurality of hydrogen chemical concentration valley portions 204, counted from the lower surface 23 of the semiconductor substrate 10 is defined as the hydrogen chemical concentration valley portion 204-m. The hydrogen chemical concentration of the hydrogen chemical concentration peak 202-m is defined as Hpm and the hydrogen chemical concentration of the hydrogen chemical concentration valley portion 204-m is defined as Hvm.

In FIG. 8, the m^{th} (m is an integer from 1 to k) peak, among the plurality of carrier concentration peaks 212, counted from the lower surface 23 of the semiconductor substrate 10 is defined as the carrier concentration peak 212-m. In addition, the m^{th} (m is an integer from 1 to k−1) valley portion, among the plurality of carrier concentration valley portions 214, counted from the lower surface 23 of the semiconductor substrate 10 is defined as the carrier concentration valley portion 214-m. The hydrogen chemical concentration of the carrier concentration peak 212-m is defined as Cpm and the carrier concentration of the carrier concentration valley portion 214-m is defined as Cvm.

In FIG. 8, the mth (m is an integer from 1 to k) peak, among the plurality of hydrogen donor concentration peaks 222, counted from the lower surface 23 of the semiconductor substrate 10 is defined as the hydrogen donor concentration peak 222-m. In addition, the m^{th} (m is an integer from 1 to k−1) valley portion, among the plurality of hydrogen donor concentration valley portions 224, counted from the lower surface 23 of the semiconductor substrate 10 is defined as the hydrogen donor concentration valley portion 224-m. The hydrogen donor concentration of the hydrogen donor concentration peak 222-m is defined as Dpm and the hydrogen donor concentration of the hydrogen donor concentration valley portion 224-m is defined as Dvm.

In the high-concentration region 20 of this example, regions in which the carrier concentration and the hydrogen donor concentration are less than 7×10¹³/cm³ is less than the example of FIG. 4. In this manner, even when at least one of the oxygen concentration and the carbon concentration of the semiconductor substrate 10 is varied, the variation in the carrier concentration and the hydrogen donor concentration can be suppressed to suppress the variation in the characteristics of the semiconductor device 100. As an example, in the high-concentration region 20 in this example, the density of the hydrogen chemical concentration peak 202 in the depth direction is higher than the example of FIG. 4. In this manner, the region in which the hydrogen donor concentration is low can be reduced, and the variation in the carrier concentration and the hydrogen donor concentration can be suppressed.

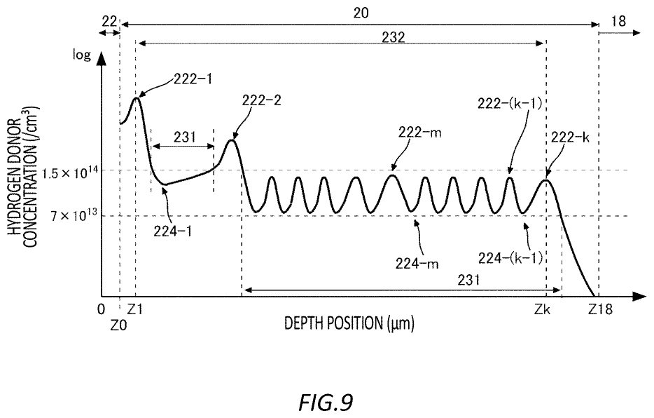

FIG. 9 illustrates an example of the hydrogen donor concentration distribution in a high-concentration region 20. The distribution in FIG. 9 is the same as the hydrogen donor concentration distribution illustrated in FIG. 8. The high-concentration region 20 has a first portion 231 with a hydrogen donor concentration of 7×10¹³/cm³ or more and 1.5×10¹⁴/cm³ or less. The high-concentration region 20 may have a single first portion 231, or may have a plurality of first portions 231 arranged discretely in the depth direction. When the local maximum of the hydrogen donor concentration peak 222-k is included in the first portion 231, the depth position Zk of the hydrogen donor concentration peak 222-k may be defined as the upper surface 21 side end portion position of the first portion 231.

In the semiconductor device 100 of this example, the length of the first portion 231 in the depth direction is 50% or more of the length (Z18−Z0) of the high-concentration region 20. When a plurality of the first portions 231 are provided, the sum of the length of the first portions 231 may be used. By providing the first portion 231 to occupy 50% or more of the high-concentration region 20, a region in which the hydrogen donor concentration is less than 7×10¹³/cm³ can be reduced. Thus, the variation in the carrier concentration and the hydrogen donor concentration can be suppressed. In addition, by setting the hydrogen donor concentration of the first portion 231 to be 1.5×10¹⁴/cm³ or less, a peak having a hydrogen donor concentration that is too high can be prevented from being provided. Thus, at the time of turning the semiconductor device 100 off or the like, voltage overshoot can be suppressed when the space charge region (depletion layer) that spans from the upper surface 21 side of the semiconductor substrate 10 reaches the first portion 231. In addition, by setting the hydrogen donor concentration of the first portion 231 to be 1.5×10¹⁴/cm³ or less, an integrated value of the hydrogen donor concentration of the high-concentration region 20 can be prevented from becoming too high.

The lower limit value of the hydrogen donor concentration of the first portion 231 may be 7×10¹³/cm³, or may be 1×10¹⁴/cm³. As described in FIG. 7, in a region where the hydrogen donor concentration is 1×10¹⁴/cm³ or more, the hydrogen donor increase amount ratio becomes mostly constant regardless of the oxygen concentration and the carbon concentration of the semiconductor substrate 10. By increasing the region where the hydrogen donor concentration is 1×10¹⁴/cm³ or more, the variation in the carrier concentration and the hydrogen donor concentration can be further suppressed. The lower limit value of the hydrogen donor concentration of the first portion 231 may be 1.1×10¹⁴/cm³, or may be 1.2×10¹⁴/cm³. The upper limit value of the hydrogen donor concentration of the first portion 231 may be 1.4×10¹⁴/cm³, or may be 1.3×10¹⁴/cm³.

In the depth direction, the length of the first portion 231 may be 60% or more, 70% or more, 80& or more, or 90% or more of the length of the high-concentration region 20. By increasing the size of the first portion 231, the variation in the carrier concentration and the hydrogen donor concentration in the high-concentration region 20 can be further suppressed. At least a part of the first portion 231 may be arranged on the upper surface 21 side relative to a center of the high-concentration region 20 in the depth direction. The high-concentration region 20 may have one or a plurality of the high-concentration peaks, each being a hydrogen donor concentration peak 222 having a hydrogen donor concentration of more than 1.5×10¹⁴/cm³. The hydrogen donor concentration of the high-concentration peak may be 5×10¹⁴/cm³ or more, 7×10¹⁴/cm³ or more, or 1×10¹⁵/cm³ or more. One or a plurality of hydrogen donor concentration peaks 222, among the plurality of hydrogen donor concentration peaks 222, closest to the lower surface 23 of the semiconductor substrate 10 may be the high-concentration peak. Although, in the example of FIG. 9, the hydrogen donor concentration peak 222-1 and the hydrogen donor concentration peak 222-2 are the high-concentration peak, three hydrogen donor concentration peaks 222 closest to the lower surface 23 of the semiconductor substrate 10 may be the high-concentration peak, or four or more hydrogen donor concentration peaks 222 may be the high-concentration peak.

In the high-concentration region 20, a region that spans from the shallowest donor concentration peak (the hydrogen donor concentration peak 222-1) to the deepest donor concentration peak (the hydrogen donor concentration peak 222-k) is defined as a second portion 232. The position (Z1, Zk) of the local maximum of each peak may be defined as an end portion position of the second portion 232 in the depth direction. The second portion 232 may include a part of the first portion 231 or may include the entire first portion 231. In the depth direction, the length of the first portion 231 may be 50% or more, 60% or more, 70% or more, 80% or more, or 90% or more of the length of the second portion 232. By increasing the size of the first portion 231, the variation in the carrier concentration and the hydrogen donor concentration in the high-concentration region 20 can be further suppressed.

A minimum value of the hydrogen donor concentration in the second portion 232 may be 7×10¹³/cm³ or more. That is, the entire second portion 232 may have a hydrogen donor concentration of 7×10¹³/cm³ or more. In this manner, the variation in the carrier concentration and the hydrogen donor concentration can be further suppressed. A minimum value of the hydrogen donor concentration in the second portion 232 may be 1×10¹⁴/cm³ or more, may be 1.1×10¹⁴/cm³ or more, or may be 1.2×10¹⁴/cm³ or more.

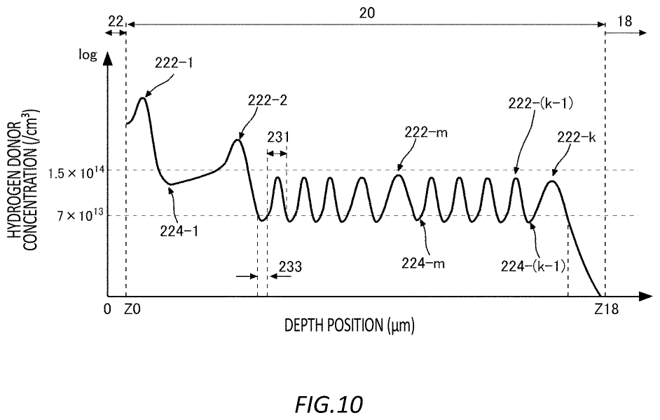

FIG. 10 illustrates another example of the hydrogen donor concentration distribution in the high-concentration region 20. The high-concentration region 20 of this example has a third portion 233 in which portions with a hydrogen donor concentration of less than 7×10¹³/cm³ are consecutively arranged in the depth direction. That is, the third portion 233 has a predetermined length in the depth direction. A plurality of the third portions 233 may be arranged discretely in the depth direction. In the example of FIG. 10, in the depth direction, the first portion 231 and the third portion 233 are alternately arranged repeatedly for two or more times. The first portion 231 and the third portion 233 may be alternately arranged repeatedly for three or more times or four or more times.

The length of the third portion 233 in the depth direction in this example is 15 μm or less. When a plurality of the third portions 233 are provided, the length of each of the third portions 233 may be 15 μm or less, or a sum of the length of the third portions 233 may be 15 μm or less. In addition, the length of each of the third portions 233 or the sum of the lengths may be 10 μm or less or may be 5 μm or less. In this manner, the variation in the carrier concentration and the hydrogen donor concentration can be suppressed.

The length of each of the third portions 233 or the sum of the lengths may be 20% or less, 15% or less, or 10% or less of the length of the high-concentration region 20 in the depth direction. In this manner, the variation in the carrier concentration and the hydrogen donor concentration can be suppressed. The length of each of the third portions 233 or the sum of the lengths may be 20% or less, 15% or less, or 10% or less of the sum of the lengths of the first portions 231 in the depth direction.

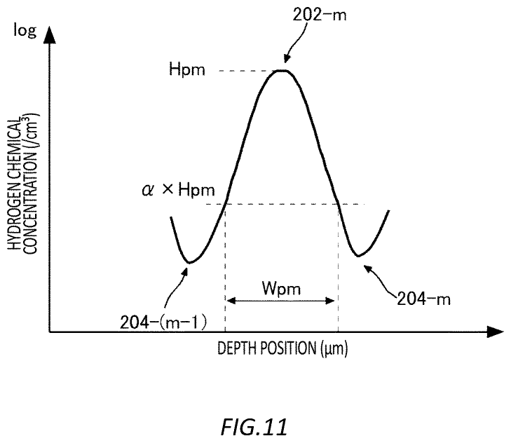

FIG. 11 is an enlarged view of the hydrogen chemical concentration peak 202-m. The peak width of the hydrogen chemical concentration peak 202-m in the depth direction is defined as a hydrogen peak width Wpm. The hydrogen peak width Wpm is a length in the depth direction of a portion in the hydrogen chemical concentration peak 202 where the hydrogen chemical concentration becomes a times or more of the local maximum value Hpm. α may be 0.1 (10%), may be 0.2 (20%), or may be 0.5 (50%). α in the example of FIG. 11 is 0.1. When a hydrogen chemical concentration of at least one of two hydrogen chemical concentration valley portions 204-(m−1), 204-m that sandwich the hydrogen chemical concentration peak 202-m in the depth direction is greater than α×Hpm, the position in said valley portion at which the hydrogen chemical concentration becomes a local minimum value an end portion position of the hydrogen peak width Wpm. When said valley portion has a flat portion in which portions where the hydrogen chemical concentration becomes the local minimum value are consecutively arranged in the depth direction, a center position of said flat portion in the depth direction may be defined as an end portion position of the hydrogen peak width Wpm. Although, in FIG. 11, the peak width of the hydrogen chemical concentration peak 202 was described, the peak widths of the carrier concentration peak 212 and the hydrogen donor concentration peak 222 may be determined similarly by using respective concentration values Cpm, Dpm.

The sum of the hydrogen peak width Wpm of the plurality of the hydrogen chemical concentration peaks 202 provided in the high-concentration region 20 may be 30% or more of the length of the high-concentration region 20 in the depth direction. In this manner, the density of the hydrogen donor concentration peak 222 in the high-concentration region 20 can be improved, and the variation in the carrier concentration and the hydrogen donor concentration can be suppressed, as described in FIG. 7. The sum of the hydrogen peak widths Wpm may be 40% or more, 50% or more, 60% or more, or 70% or more of the length of the high-concentration region 20 in the depth direction. Although, In the example of FIG. 11, description was made by using a sum of peak widths of the hydrogen chemical concentration peaks 202, instead of the sum of peak widths of the hydrogen chemical concentration peaks 202, a sum of peak widths of the carrier concentration peaks 212 may be used, or a sum of peak widths of the hydrogen donor concentration peaks 222 may be used.

As illustrated in FIG. 8, in the high-concentration region 20, hydrogen chemical concentration peaks 202 (referred to as a same-concentration peak) having a same degree of hydrogen chemical concentration may be arranged consecutively in the depth direction. The same-concentration peak has a hydrogen chemical concentration that is 0.8 times or more and 1.2 times or less of a hydrogen chemical concentration of at least one hydrogen chemical concentration peak 202 arranged adjacent thereto in the depth direction. For example, when the hydrogen chemical concentration Hpm of the hydrogen chemical concentration peak 202-m is 0.8 times or more and 1.2 times or less of at least one of the hydrogen chemical concentration Hp(m−1) of the hydrogen chemical concentration peak 202-(m−1) or the hydrogen chemical concentration Hp(m+1) of the hydrogen chemical concentration peak 202-(m+1), the hydrogen chemical concentration peak 202-m is a same-concentration peak.

Three or more of the same-concentration peaks may be arranged consecutively in the depth direction in the high-concentration region 20, the upper region 242, or the first portion 231. Four or more or five or more of the same-concentration peaks may be arranged consecutively. The interval between the same-concentration peaks may or may not be constant. In the present specification, in an example described by using the same-concentration peak of the hydrogen chemical concentration peak 202, instead of the same-concentration peak of the hydrogen chemical concentration peak 202, the same-concentration peak of the carrier concentration peak 212 may be used or the same-concentration peak of the hydrogen donor concentration peak 222 may be used. The same-concentration peak also has a concentration that is 0.8 times or more and 1.2 times or less of the concentration of at least one concentration peak arranged adjacent thereto in the depth direction in the carrier concentration peak 212 and the hydrogen donor concentration peak 222.

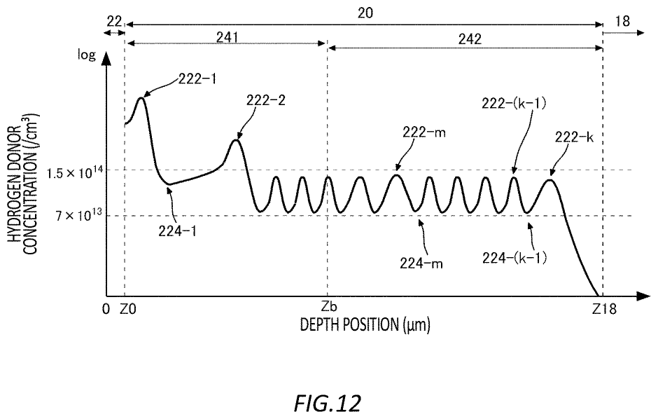

FIG. 12 illustrates a hydrogen donor concentration distribution. The hydrogen donor concentration distribution of FIG. 12 is the same as the hydrogen donor concentration distribution in the example of FIG. 8. The high-concentration region 20 of this example has a lower region 241 and an upper region 242. The lower region 241 is a region on a lower-surface 23 side relative to a predetermined boundary position Zb in the depth direction, and the upper region 242 is a region on an upper surface 21 side relative to the boundary position Zb.

The boundary position Zb may be a position that is away from the lower surface 23 of the semiconductor substrate 10 in the depth direction by 20 μm, may be a center position of the high-concentration region 20 in the depth direction, may be a position of the hydrogen chemical concentration valley portion 204-3, or may be a position away from the lower surface 23 of the semiconductor substrate 10 by 25% of a thickness of the semiconductor substrate 10. In an embodiment including at least one of the lower region 241 and the upper region 242 described in the present specification, any of the boundary position Zbs described above may be used.

In this example, as an example, the boundary position Zb is a position that is away from the lower surface 23 of the semiconductor substrate 10 in the depth direction by 20 μm. That is, the upper region 242 is a portion in the high-concentration region 20 that is away from the lower surface 23 of the semiconductor substrate 10 in the depth direction by 20 μm or more. In the upper region 242, three or more of the same-concentration peaks described in FIG. 8 may be arranged consecutively in the depth direction. Four or more or five or more of the same-concentration peaks may be arranged consecutively in the depth direction in the upper region 242. Half or more, ¾ or more, or all of the hydrogen donor concentration peaks 222 included in the upper region 242 may be the same-concentration peak. By arranging the same-concentration peak in the upper region 242, voltage overshoot can be suppress when the space charge region reaches the upper region 242 since there is fewer concentration peak that stands out in the upper region 242.

The sum of the hydrogen peak widths Wpm (see FIG. 11) of the the hydrogen chemical concentration peaks 202 arranged in the upper region 242 may be 30% or more of the length of the upper region 242 in the depth direction. The sum of the hydrogen peak widths Wpm in the upper region 242 may be 40% or more, 50% or more, 60% or more, or 70% or more of the length of the upper region 242 in the depth direction.

In the first portion 231 describe in FIG. 9, three or more of the same-concentration peaks may be arranged consecutively in the depth direction. Four or more or five or more of the same-concentration peaks may be arranged consecutively in the depth direction in the first portion 231. Half or more, ¾ or more, or all of the hydrogen donor concentration peaks 222 included in the first portion 231 may be the same-concentration peak.

The sum of the hydrogen peak widths Wpm (see FIG. 11) of the hydrogen chemical concentration peaks 202 arranged in the first portion 231 may be 30% or more of the length of the first portion 231 in the depth direction. The sum of the hydrogen peak widths Wpm in the first portion 231 may be 40% or more, 50% or more, 60% or more, or 70% or more of the length of the first portion 231 in the depth direction.

50% or more of the upper region 242 in the depth direction may be the first portion 231. 60% or more, 70% or more, 80% or more, 90% or more, or the entirety of the upper region 242 in the depth direction may be the first portion 231. By arranging the first portion 231 in the upper region 242, voltage overshoot can be suppressed when the space charge region reaches the upper region 242.

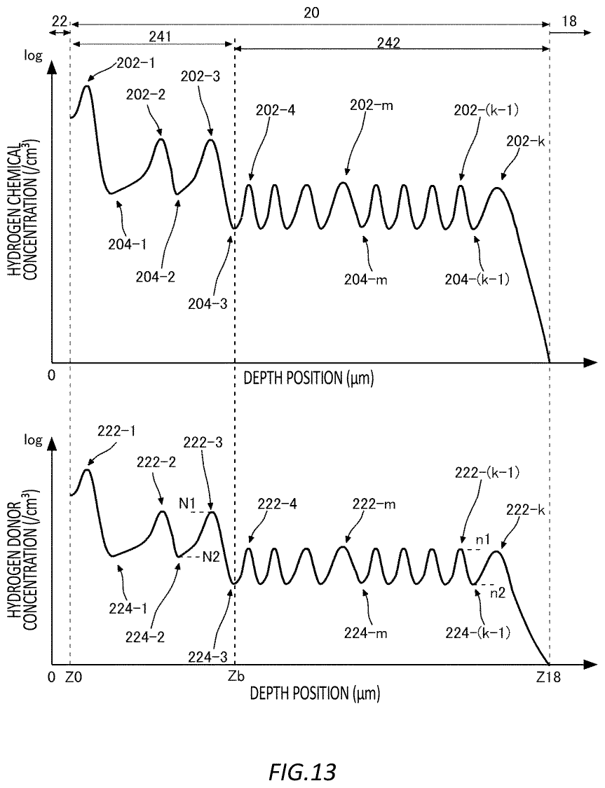

FIG. 13 illustrates another example of the hydrogen chemical concentration distribution and the hydrogen donor concentration distribution. The carrier concentration distribution becomes a distribution in which the bulk donor concentration Db is added to the hydrogen donor concentration distribution. In this example, the hydrogen chemical concentration is greatly changed between the hydrogen chemical concentration peak 202-3 and the hydrogen chemical concentration peak 202-4. The hydrogen chemical concentration peak 202-3 is an example of a third hydrogen concentration peak. The hydrogen chemical concentration of the hydrogen chemical concentration peak 202-3 may be 1.5 times or more, twice or more, five times or more, or ten times or more of the hydrogen chemical concentration of the hydrogen chemical concentration peak 202-4. The hydrogen donor concentration of the hydrogen donor concentration peak 222-3 may be 1.5 times or more, twice or more, five times or more, or ten times or more of the hydrogen donor concentration of the hydrogen donor concentration peak 222-4. Other distribution is similar to that in the example described in FIG. 4 to FIG. 12.

In this example, the hydrogen donor concentration peak 222-(k−1), among the plurality of hydrogen donor concentration peaks 222, that is second closest to the upper surface 21 of the semiconductor substrate 10 is defined as a second deepest donor concentration peak. In addition, the hydrogen donor concentration of the hydrogen donor concentration peak 222-(k−1) is defined as n1 and the hydrogen donor concentration of the hydrogen donor concentration valley portion 224-(k−1) is defined as n2. The hydrogen donor concentration peak 222-(k−1) and the hydrogen donor concentration valley portion 224-(k−1) may be included in the first portion 231 (see FIG. 9). A value n1/n2 obtained by dividing the hydrogen donor concentration n1 by the hydrogen donor concentration n 2 may be 1.1 or more and 2.0 or less. In this manner, the hydrogen donor concentration peak 222-(k−1) with a relatively small amplitude can be arranged between the hydrogen donor concentration peak 222-k and the hydrogen donor concentration peak 222-4, as compared to the reference example illustrated in FIG. 4. In this manner, the variation of the carrier concentration and the hydrogen donor concentration between the hydrogen donor concentration peak 222-k and the hydrogen donor concentration peak 222-4 can be suppressed. The value n1/n2 may be 1.2 or more or may be 1.3 or more. The value n1/n2 may be 1.9 or less or may be 1.8 or less. Note that, the content described with respect to the value n1/n2 can be applied to embodiments other than FIG. 13.

In this example, the boundary position Zb between the upper region 242 and the lower region 241 is a position of the hydrogen chemical concentration valley portion 204-3 or the hydrogen donor concentration valley portion 224-3. That is, a region that spans from the lower surface 23 of the semiconductor substrate 10 to a region including the hydrogen chemical concentration peak 202-3 is defined as the lower region 241, and a region on an upper surface 21 side of the semiconductor substrate 10 relative to the hydrogen chemical concentration peak 202-3 is defined as the upper region 242.

The hydrogen donor concentration peak 222-3, among the hydrogen donor concentration peaks 222 in the lower region 241, that is farthest from the lower surface 23 of the semiconductor substrate 10 is referred to as a lower-side deepest donor concentration peak. The hydrogen donor concentration valley portion 224-2, among the hydrogen donor concentration valley portions 224 in the lower region 241, that is farthest from the lower surface 23 of the semiconductor substrate 10 is referred to as a lower-side deepest donor concentration valley portion. The hydrogen donor concentration of the hydrogen donor concentration peak 222-3 is defined as N1 and the hydrogen donor concentration of the hydrogen donor concentration valley portion 224-2 is defined as N2. A value N1/N2 obtained by dividing the hydrogen donor concentration N1 by the hydrogen donor concentration N2 may be 1.2 or more and 4.0 or less. In this manner, the hydrogen donor concentration peak 222 with a a relatively large amplitude can be arranged in the lower region 241 to prevent the space charge region from reaching the collector region 22. The value N1/N2 may be 2 or more or may be 2.5 or more. The value N1/N2 may be 3.5 or less or may be 3 or less. Note that, the content described with respect to the value N1/N2 can be applied to embodiments other than FIG. 13.

The value N1/N2 is defined as a and the value n1/n2 is defined as b. A value a/b obtained by dividing the value A by the value B may be greater than 0.5. The value a/b may be greater than 1 or may be 2 or more.

The hydrogen donor concentration n 1 may be 0.5 times or less of the hydrogen donor concentration N 1. In this manner, the hydrogen donor concentration peak 222 with low concentration can be arranged in the upper region 242. All of the hydrogen donor concentration peaks 222 included in the upper region 242 may have a hydrogen donor concentration n1. The hydrogen donor concentration n1 may be 0.2 times or less or 0.1 times or less of the hydrogen donor concentration N 1.

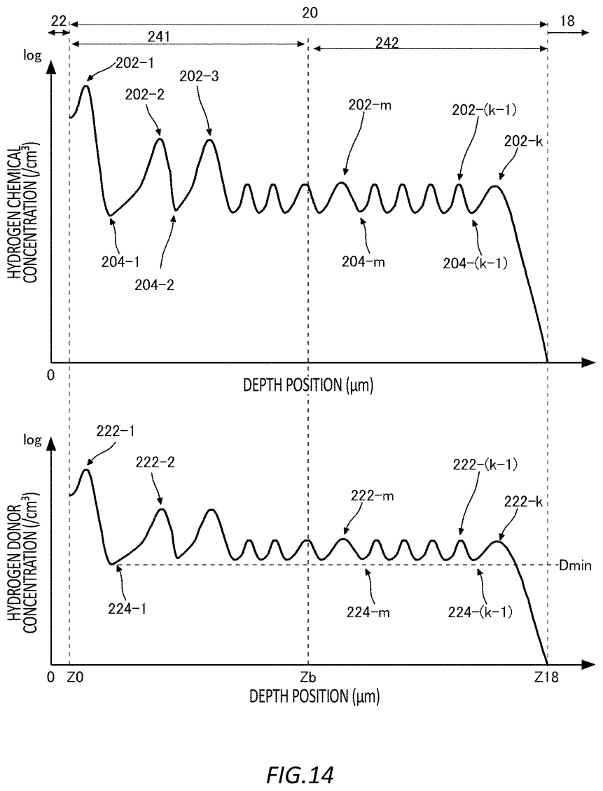

FIG. 14 illustrates another example of the hydrogen chemical concentration distribution and the hydrogen donor concentration distribution. In this example, the boundary position Zb between the lower region 241 and the upper region 242 is a center of the high-concentration region 20 in the depth direction. That is, in the high-concentration region 20, a region on the lower-surface 23 side relative to the center in the depth direction is defined as the lower region 241, and a region on the upper surface 21 side is defined as the upper region 242.

In this example, the hydrogen donor concentration of at least one hydrogen donor concentration valley portion 224 in the upper region 242 is higher than the hydrogen donor concentration of at least one hydrogen donor concentration valley portion 224 in the lower region 241. The hydrogen donor concentration of at least one hydrogen donor concentration valley portion 224 in the first portion 231 (see FIG. 9) included in the upper region 242 may be higher than the hydrogen donor concentration of at least one hydrogen donor concentration valley portion 224 in the lower region 241.

In the example of FIG. 14, the hydrogen donor concentration of the hydrogen donor concentration valley portion 224-1 is a minimum value Dmin of the hydrogen donor concentration in the lower region 241. The hydrogen donor concentration of at least one hydrogen donor concentration valley portion 224 in the upper region 242 (or the first portion 231 of the upper region 242) is greater than the minimum value Dmin. The hydrogen donor concentration of a plurality of hydrogen donor concentration valley portions 224 in the upper region 242 (or the first portion 231 of the upper region 242) may be greater than the minimum value Dmin, the hydrogen donor concentration of half or more of the hydrogen donor concentration valley portions 224 in the upper region 242 (or the first portion 231 of the upper region 242) may be greater than the minimum value Dmin, or the hydrogen donor concentration of all of the hydrogen donor concentration valley portions 224 in the upper region 242 (or the first portion 231 of the upper region 242) may be greater than the minimum value Dmin. In this manner, the hydrogen donor concentration of the upper region 242 can be increased to suppress the variation in the carrier concentration and the hydrogen donor concentration.

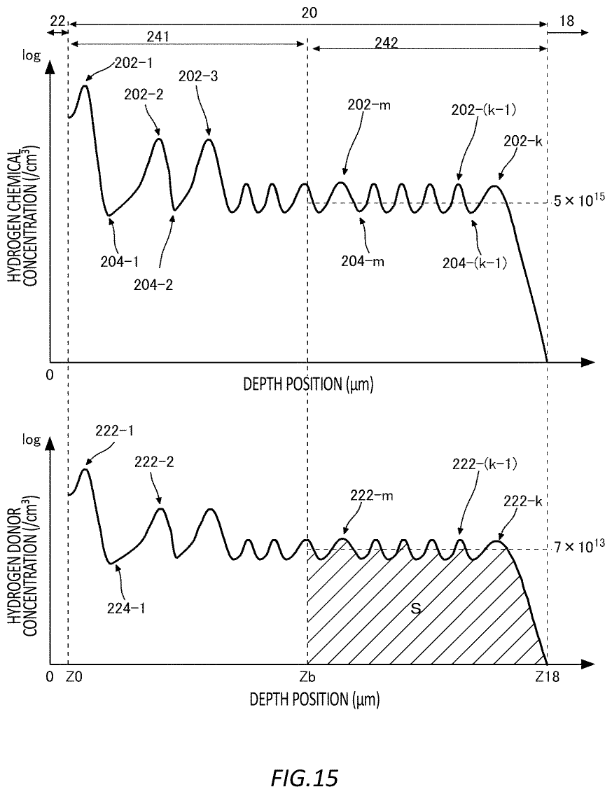

FIG. 15 illustrates an example of a boundary position Zb. The boundary position Zb of this example is a position that is away from the lower surface 23 of the semiconductor substrate 10 in the depth direction by 20 μm. A value obtained by integrating the hydrogen donor concentrations in the upper region 242 in the depth direction is defined as an integrated concentration S (/cm²). The integrated concentration S corresponds to a area of a portion that is hatched with diagonal lines in FIG. 15. In this example, the integrated concentration S is 8×10¹⁰/cm² or more and 2×10¹¹/cm² or less.

In this manner, the hydrogen donor concentration in the upper region 242 can be increased to some extent to suppress the variation in the carrier concentration and the hydrogen donor concentration. In addition, the hydrogen donor concentration in the upper region 242 can be suppressed from becoming too high, and voltage overshoot can be suppressed when the space charge region reaches the upper region 242. The integrated concentration S may be 1×10¹¹/cm² or more, or may be 1.2×10¹¹/cm² or more. The integrated concentration S may be 1.8×10¹¹/cm² or less, or may be 1.6×10¹¹/cm² or less.

The sum of full width at half maximum of the hydrogen chemical concentration peaks 202, among the hydrogen chemical concentration peaks 202 in the upper region 242, with a hydrogen chemical concentration at the local maximum of 5×10¹⁵/cm³ or more may be 20% or more and 90% or less of the length of the upper region 242 in the depth direction. In the first portion 231 included in the upper region 242, the sum of full width at half maximum of the hydrogen chemical concentration peaks 202 described above may be 20% or more and 90% or less of the length of the first portion 231 included in the upper region 242 in the depth direction.

In the example of FIG. 15, in all of the hydrogen chemical concentration peaks 202 in the upper region 242, the hydrogen chemical concentration at the local maximum is 5×10¹⁵/cm³ or more. As described in FIG. 11, when the hydrogen chemical concentration of at least one of the two hydrogen chemical concentration valley portions 204 that sandwich the hydrogen chemical concentration peak 202 is greater than 50% of the hydrogen chemical concentration at the local maximum of the hydrogen chemical concentration peak 202, the position of that hydrogen chemical concentration valley portion 204 is defined as an end portion position of full width at half maximum of the hydrogen chemical concentration peak 202. The sum of full width at half maximum of the hydrogen chemical concentration peaks 202 described above may be 30% or more, 40% or more, 50% or more, or 60% or more of the length of the upper region 242 in the depth direction. In the first portion 231 included in the upper region 242, the sum of full width at half maximum of the hydrogen chemical concentration peaks 202 described above may be 40% or more, 50% or more, or 60% or more of the length of the first portion 231 included in the upper region 242 in the depth direction.

A sum of full width at half maximum of the hydrogen donor concentration peaks 222, among the hydrogen donor concentration peaks 222 in the upper region 242, with a hydrogen donor concentration of at the local maximum of 7×10¹³/cm³ or more may be 30% or more of the length of the upper region 242 in the depth direction. In the first portion 231 included in the upper region 242, the sum of full width at half maximum of the hydrogen donor concentration peaks 222 described above may be 30% or more of the length of the first portion 231 included in the upper region 242 in the depth direction.

As described in FIG. 11, when the hydrogen donor concentration of at least one of the two hydrogen donor concentration valley portions 224 that sandwich the hydrogen donor concentration peak 222 is greater than 50% of the hydrogen donor concentration at the local maximum of the hydrogen donor concentration peak 222, the position of that hydrogen donor concentration valley portion 224 is defined as an end portion position of full width at half maximum of the hydrogen donor concentration peak 222. The sum of full width at half maximum of the hydrogen donor concentration peaks 222 described above may be 40% or more, 50% or more, 60% or more, or 70% or more of the length of the upper region 242 in the depth direction. The sum of full width at half maximum of the hydrogen donor concentration peaks 222 described above may be 90% or less of the length of the upper region 242 in the depth direction. In the first portion 231 included in the upper region 242, the sum of full width at half maximum of the hydrogen donor concentration peaks 222 described above may be 40% or more, 50% or more, or 60% or more, or 70% or more of the length of the first portion 231 included in the upper region 242 in the depth direction.

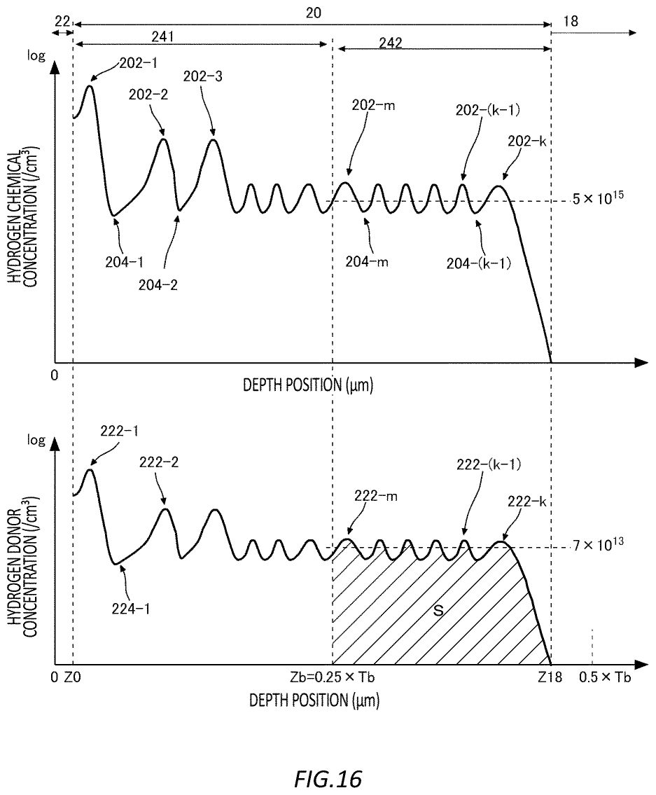

FIG. 16 illustrates another example of the boundary position Zb. In this example, the thickness of the semiconductor substrate 10 in the depth direction is defined as Tb. The boundary position Zb of this example is a position where the distance from the lower surface 23 of the semiconductor substrate 10 becomes 25% of the thickness of the semiconductor substrate 10 (0.25×Tb). The upper region 242 of this example is provided in at least a part of a range in which the distance from the lower surface 23 of the semiconductor substrate 10 is 0.25×Tb or more and 0.5×Tb or less. In this example, the entire upper region 242 is arranged in a depth range of 0.25×Tb to 0.5×Tb. The upper region 242 may be provided in the entire depth range of 0.25×Tb to 0.5×Tb. When the high-concentration region 20 is also extended to the upper surface 21 side relative to the depth position of 0.5×Tb, the region from 0.25×Tb to 0.5×Tb may be defined as the upper region 242.

The structure other than the position of the upper region 242 is similar to that in any of the examples described in each figure in the present specification. For example, the integrated concentration S in the upper region 242, the sum of peak widths of the hydrogen chemical concentration peaks 202, and the sum of peak widths of the hydrogen donor concentration peaks 222 may be similar to those in the example of FIG. 15.

In each example described in each figure of the present specification, the carbon concentration of the semiconductor substrate 10 may be 1×10¹³/cm³ or more and 5×10¹⁵/cm³ or less. An average value of carbon concentration in the entire semiconductor substrate 10 may be uses as the carbon concentration of the semiconductor substrate 10. The carbon concentration of the semiconductor substrate 10 may be 5×10¹³/cm³ or more, or may be 1×10¹⁴/cm³ or more. The carbon concentration of the semiconductor substrate 10 may be 3×10¹⁵/cm³ or less, or may be 1×10¹⁵/cm³ or less.

The hydrogen donor of the high-concentration region 20 may include an interstitial donor Si—H. As an example, the hydrogen donor of the high-concentration region 20 includes a VOH defect and an interstitial donor SiH. The concentration of the interstitial donor in the high-concentration region 20 may be 30% or more of the concentration of the hydrogen donor. An integrated value of the concentration of the interstitial donor in the high-concentration region 20 in the depth direction may be 30% or more, 40% or more, or 50% or more of an integrated value of the hydrogen donor concentration in the high-concentration region 20 in the depth direction. The extent to which the interstitial donor Si—H is formed is relatively less influenced by the oxygen concentration and the carbon concentration of the semiconductor substrate 10. Thus, by increasing the ratio of the interstitial donor Si—H, the variation in the carrier concentration and the hydrogen donor concentration in the high-concentration region 20 can be suppressed. An integrated value of the concentration of the interstitial donor in the first portion 231 in the depth direction may be 30% or more, 40% or more, or 50% or more of an integrated value of the hydrogen donor concentration in the first portion 231 in the depth direction. As an example, the concentration of the interstitial donor Si—H may be a value obtained by performing Gaussian fitting of a peak portion of the carrier concentration distribution and subtracting the bulk donor concentration Db.

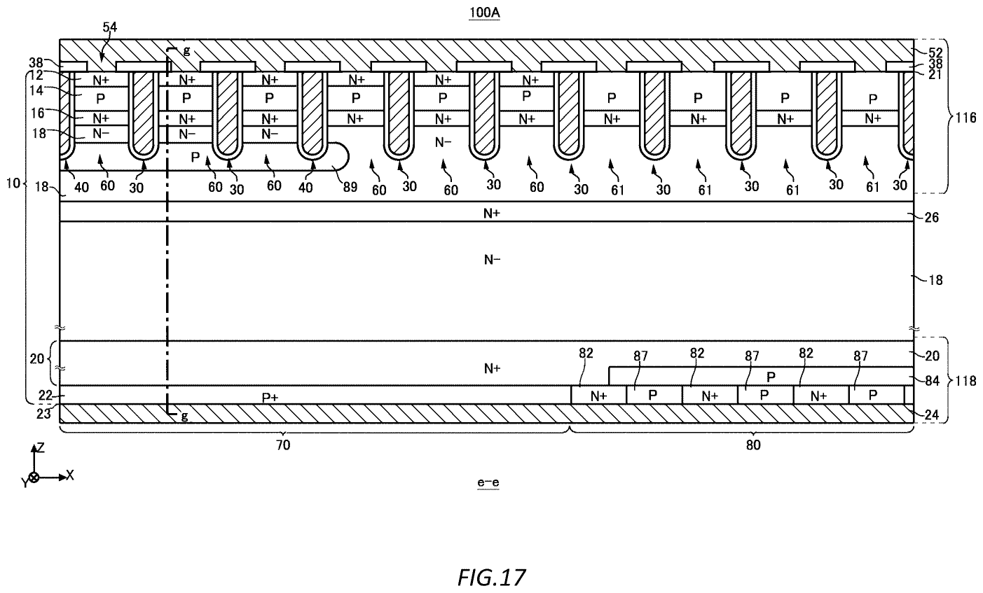

FIG. 17 is an e-e cross sectional view illustrating an example of a semiconductor device 100A according to another embodiment of the present invention. Each example described in FIG. 1 to FIG. 16 can be combined with a semiconductor device 100A illustrated in FIG. 17 and thereafter, and some of the components in each example described in FIG. 1 to FIG. 16 can also be extracted to be applied to the semiconductor device 100A. In addition, some of the components of the semiconductor device 100A can be extracted to be applied to the semiconductor device 100 described in FIG. 1 to FIG. 16.

The semiconductor device 100A may further be provided with, in addition to each component described in FIG. 1 to FIG. 16, at least one of a second high-concentration region 26 of an N type, an electric field reduction region 89 of a P type, a floating region 84 of a P type, or a second cathode region 87 of a P type. Note that, in the semiconductor device 100A, the second high-concentration region 26, the electric field reduction region 89 of the P type, the floating region 84 of the P type, and the second cathode region 87 of the P type are not essential. The semiconductor device 100A may be provided with one of these, may be provided a plurality of these, may be provided with all of these, or may be provided with none of these.

The electric field reduction region 89 may be electrically floating. The electric field reduction region 89 may be in contact with a bottom portion of at least one gate trench portion 40. The electric field reduction region 89 may cover the bottom portion of the gate trench portion 40. By being provided with the electric field reduction region 89, the electric field strength at the bottom portion of the trench portion can be reduced. The drift region 18 may be provided between the electric field reduction region 89 and the base region 14. In the example of FIG. 17, the drift region 18 is provided between the electric field reduction region 89 and the accumulation region 16.

The electric field reduction region 89 may be provided for all of the gate trench portions 40. The electric field reduction region 89 may or may not be provided for the dummy trench portion 30. In the example of FIG. 17, the electric field reduction region 89 is provided for a dummy trench portion 30 sandwiched between two gate trench portions 40. The electric field reduction region 89 may be provided consecutively throughout the plurality of trench portions provided side by side in the X axis direction. At least one electric field reduction region 89 may be provided in each transistor portion 70. The electric field reduction region 89 may be provided in the diode portion 80, or may not be provided.

The second high-concentration region 26 is a region with a higher doping concentration than the drift region 18. The second high-concentration region 26 may have a concentration peak of a hydrogen donor, or may have a concentration peak of another donor. The second high-concentration region 26 of this example is provided on the upper surface 21 side of the semiconductor substrate 10. The second high-concentration region 26 of this example is arranged below the bottom portion of the trench portion. The second high-concentration region 26 may be arranged below the electric field reduction region 89. The second high-concentration region 26 may or may not be in contact with the electric field reduction region 89. In this example, the drift region 18 is provided between the second high-concentration region 26 and the electric field reduction region 89.

The floating region 84 is provided above the cathode region 82. The floating region 84 may be separated from the collector region 22. The floating region 84 may be provided between the high-concentration region 20 and the cathode region 82. An end on the transistor portion 70 side of the floating region 84 may be positioned inside the cathode region 82 in a top view. By providing the floating region 84, the carrier implantation from the cathode region 82 can be suppressed, allowing the characteristics of the diode portion 80 to be adjusted.

The second cathode region 87 is arranged side by side with the cathode region 82 in the X axis direction. The diode portion 80 of this example has arranged therein alternately and repeatedly for multiple times, in the X axis direction, the cathode region 82 and the second cathode region 87. By providing the second cathode region 87, the area of the cathode region 82 is limited and carrier implantation from the lower surface side of the diode portion 80 is suppressed, allowing the characteristics of the diode portion 80 to be adjusted.

In the semiconductor device 100A, the dopant of the bulk donor of the semiconductor substrate 10 may be antimony. In each example of FIG. 1 to FIG. 16, the bulk donor may also be antimony. The major dopant in the drift region 18 may be antimony. A major dopant in a region may, as an example, be defined as a dopant, among one or more types of dopants that present a conductivity type of an N type or P type in the region, that presents the highest doping concentration, which determines the conductivity type of the region. When the drift region 18 is of an N type, the major dopant in the drift region 18 is a dopant with a highest doping concentration, among the N type dopants. For the doping concentration of each dopant, a value obtained by dividing an integrated concentration obtained by integrating the doping concentration in the drift region 18 in the depth direction by a distance of the integrated range in the depth direction may be used. The doping concentration of the dopant may be a value obtained by multiplying the chemical concentration of the dopant by an electric activation rate. When the dopant is phosphorous, antimony, arsenic, or boron, the value of the electric activation rate is 95% or more, so the electric activation rate may be considered to be substantially 100%.

The net doping concentration of the drift region 18 may be a sum of doping concentration when defining, for the doping concentration of each of the one or more types of dopants representing a conductivity type of an N type or a P type in the drift region 18, the doping concentration of an N type dopant (that is, the donor concentration) as + and the doping concentration of a P type dopant (that is, the acceptor concentration) as −. That is, when the donor concentration of i types of N type dopants as ΣN_{D} (i) and the acceptor concentration of j types of P type dopants as ΣN_{A}(j), the net doping concentration N of the drift region 18 is N=ΣN_{D}(i)−ΣN_{A}(j). Note that, Σ is a symbol of a sum, and a suffix i or j that should be written below each symbol Σ is omitted. As an example, when there are two types of N type dopants in the drift region 18 and also two types of P type dopants in the drift region 18, the net doping concentration N of the drift region 18 is N=N_{D}(1)+N_{D}(2)−{N_{A}(1)+N_{A}(2)}. The net doping concentration N of the drift region 18 may be a net doping concentration N of the entire drift region 18, or may be a net doping concentration N in a depth region in a part of the drift region 18. The major dopant in the drift region 18 is a dopant with a highest value of N_{D}(i).

The major dopant in the drift region 18 may be the bulk donor distributed throughout the entire semiconductor substrate 10, and the bulk donor may be antimony. At any depth position in the drift region 18, the major dopant in the drift region 18 may be the major dopant throughout the entire semiconductor device 100 in a top view, or may be the major dopant in an area that corresponds to 90% or more of the area of the entire semiconductor device 100 in a top view.

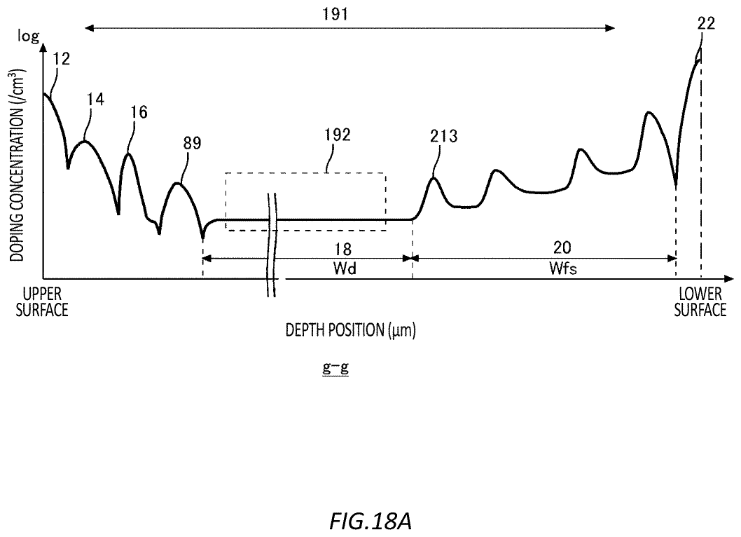

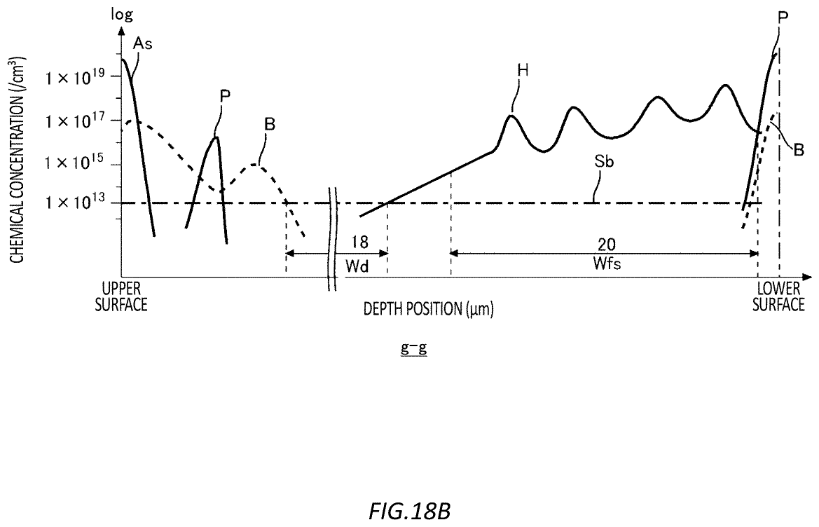

FIG. 18A illustrates an example of the doping concentration distribution at line g-g in FIG. 17.

The line g-g is a line parallel to the Z axis that passes through the electric field reduction region 89. A horizontal axis in FIG. 18A represents a depth position (a position in the Z axis direction) in the semiconductor substrate 10. In FIG. 18A, the upper surface 21 of the semiconductor substrate 10 is defined as a reference position.

The emitter region 12, the base region 14, the accumulation region 16, and the electric field reduction region 89 each have one or more concentration peaks. In this example, the accumulation region 16 and the electric field reduction region 89 are in contact with each other.

The drift region 18 of this example is provided from a lower end of the electric field reduction region 89 to an upper end of the high-concentration region 20. The semiconductor substrate 10 of this example is not provided with the second high-concentration region 26. The drift region 18 may have a substantially uniform doping concentration from the lower end of the electric field reduction region 89 to the upper end of the high-concentration region 20. In another example, the drift region 18 may have a substantially uniform doping concentration from the lower end of the second high-concentration region 26 to the upper end of the high-concentration region 20. Substantially uniform may refer to the fact that a maximum value of the doping concentration is 200% or less, 150% or less, 130% or less, or 110% or less of a minimum value of the doping concentration.

The high-concentration region 20 has one or more doping concentration peaks 213 in the depth direction. The doping concentration peak 213 corresponds to the carrier concentration peak 212 described in FIG. 1 to FIG. 16. The high-concentration region 20 may have four or less doping concentration peaks 213 as illustrated in FIG. 18A, or may have more than four doping concentration peaks 213. The high-concentration region 20 may have the same structure as any of the examples described in FIG. 1 to FIG. 16. In this example, the length of the drift region 18 in the depth direction is defined as Wd (μm), and the length of the high-concentration region 20 in the depth direction is defined as Wfs (μm).

The collector region 22 is provided between the high-concentration region 20 and the lower surface 23. In the diode portion 80, the cathode region 82 or the second cathode region 87 is provided instead of the collector region 22.

In the present specification, a predetermined range of the semiconductor substrate 10 in the depth direction may be referred to as a first depth range 191. In addition, a predetermined range of the drift region 18 in the depth direction may be referred to as a second depth range 192. The first depth range 191 and the second depth range 192 will be described below.

FIG. 18B illustrates an example of the chemical concentration distribution of each dopant at line g-g in FIG. 17. Note that, in FIG. 18B, the chemical concentration distribution of the dopant in the cathode region 82 illustrated. In the example of FIG. 18B, each distribution of hydrogen H, phosphorous P, boron B, antimony Sb, and arsenic As in the semiconductor substrate 10 is illustrated.

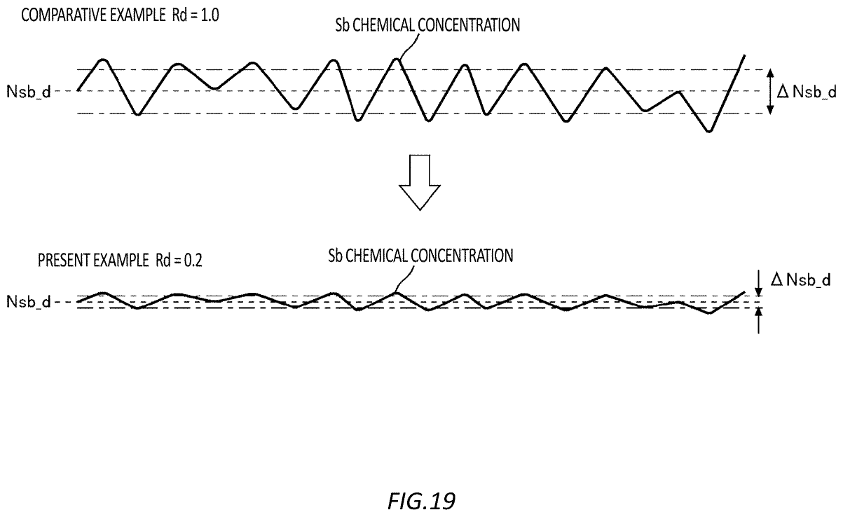

The bulk donor of the semiconductor substrate 10 in this example is antimony. The antimony chemical concentration is substantially uniform inside the semiconductor substrate 10. As illustrated in FIG. 19, the chemical concentration of antimony included in the semiconductor substrate 10 may be 1×10¹²/cm³ or more and 1×10¹⁴/cm³ or less.

The major dopant in the drift region 18 is antimony. The drift region 18 of this example is not provided with a chemical concentration peak of a dopant other than antimony. The antimony chemical concentration may be higher than the chemical concentration of any other dopants in the entirety of the depth direction of the drift region 18.

A hydrogen donor may be used for the major dopant in the high-concentration region 20. The hydrogen chemical concentration included in the semiconductor substrate 10 may be 1×10¹⁵/cm³ or more and 5×10¹⁸/cm³ or less. A peak value may be used for the chemical concentration of each dopant.

Boron may be used for the major dopant in the base region 14, the well region 11, or the contact region 15. The boron chemical concentration included in the semiconductor substrate 10 may be 1×10¹⁶/cm³ or more and 1×10¹⁹/cm³ or less.

Phosphorous may be used for the major dopant in the cathode region 82 or the accumulation region 16. The phosphorous chemical concentration included in the semiconductor substrate 10 may be 1×10¹⁶/cm³ or more and 5×10¹⁹/cm³ or less.

Arsenic may be used for the major dopant in the emitter region 12. The arsenic chemical concentration included in the semiconductor substrate 10 may be 1×10¹⁹/cm³ or more and 1×10²⁰/cm³ or less. The magnitude relationship of chemical concentrations of dopants included in the semiconductor substrate 10 may be antimony chemical concentration<hydrogen chemical concentration<boron chemical concentration or phosphorous chemical concentration<arsenic chemical concentration.

An average concentration of antimony chemical concentration in the first depth range 191 of the semiconductor substrate 10 is defined as <Nsb> and a standard deviation of antimony chemical concentration in the first depth range 191 is defined as <ΔNsb>. A thickness of the first depth range 191 may be 50% or more, 60% or more, or 70% or more of the thickness of the semiconductor substrate 10. The thickness of the first depth range 191 may be 100% or less, less than 100%, 90% or less, or 80% or less of the thickness of the semiconductor substrate 10.

A ratio R of the standard deviation of antimony chemical concentration <ΔNsb> to the average concentration of antimony chemical concentration <Nsb> is defined as R=<ΔNsb>/<Nsb>. The ratio R may be 0.2 or less, 0.15 or less, 0.1 or less, or 0.08 or less. The ratio R may be 0.001 or more, 0.01 or more, or 0.03 or more. For example, the ratio R in the first depth range 191 being 0.2 or less means that such a first depth range 191 that the ratio R becomes 0.2 or less exists. In addition, the thickness of the first depth range 191 being 50% or more, for example, of the thickness of the semiconductor substrate 10 means that a first depth range 191 that satisfies a condition of the above-described ratio R and has a thickness of 50% or more of the thickness of the semiconductor substrate 10 exists.

The upper end of the first depth range 191 may or may not be identical to the upper surface 21 of the semiconductor substrate 10. The lower end of the first depth range 191 may or may not be identical to the lower surface 23 of the semiconductor substrate 10. At least a part of the drift region 18 in the depth direction is included in the first depth range 191. In the first depth range 191, half or more of the drift region 18 in the depth direction may be included, or the entire drift region 18 be included.

In the depth direction of the semiconductor substrate 10, the thickness of the drift region 18 may be 20% or more and 90% or less of the thickness of the semiconductor substrate 10. The thickness of the drift region 18 may be 40% or more, 50% or more, or 60% or more of the thickness of the semiconductor substrate 10.

FIG. 19 illustrates the distribution of an antimony chemical concentration in a second depth range 192 of a drift region 18. An average concentration of antimony chemical concentration in the second depth range 192 is defined as <Nsb_d>, and a standard deviation of antimony chemical concentration in the second depth range 192 is defined as <ΔNsb_d>. The thickness of the second depth range 192 is 50% or more and 100% or less of the thickness Wd of the drift region 18. The thickness of the second depth range 192 may be 70% or more, 80% or more, or 90% or more of the thickness of the drift region 18.

A ratio Rd of the standard deviation of antimony chemical concentration <ΔNsb_d> to the average concentration of antimony chemical concentration <Nsb_d> is defined as Rd=<ΔNsb_d>/<Nsb_d>. The ratio Rd may be 0.2 or less, 0.15 or less, 0.1 or less, or 0.08 or less. The ratio Rd may be 0.001 or more, 0.01 or more, or 0.03 or more. Since the rate of the antimony becoming a donor is 95% or more of the antimony chemical concentration, the above-described ratio Rd may be the ratio of the donor concentration or the doping concentration.

As described in the description related to FIG. 1 to FIG. 16, in the semiconductor device 100 or the semiconductor device 100A, an impurity element added to the semiconductor substrate 10 and its concentration influence the variation in the characteristics of each element at the manufacturing stage. The semiconductor device 100A provides a configuration in which variation in the characteristics of each element can be suppressed at the manufacturing stage to reduce the cost.

As illustrated in FIG. 19, by reducing the ratio Rd that indicates the variation in the major dopant, the variation in the doping concentration in the second depth range 192 can be reduced. In this manner, the variation in the characteristics of the semiconductor device 100A can be suppressed. In the drift region 18, very few dopants other than the bulk donor may exist. For example, in the drift region 18, the concentration of the bulk donor may be twice or more, five times or more, or ten times or more of the concentration of other dopants. Thus, by suppressing the variation in the concentration of the bulk donor, which is the major dopant in the drift region 18, the variation in the doping concentration in the drift region 18 can be easily suppressed. As will be described below, by using antimony for the major dopant in the drift region 18, the ratio Rd in the drift region 18 can be easily reduced.

The variation in the characteristics of the semiconductor device 100A can also be suppressed by reducing the ratio R in the first depth range 191. By using antimony for the bulk donor, the ratio R can be easily reduced.

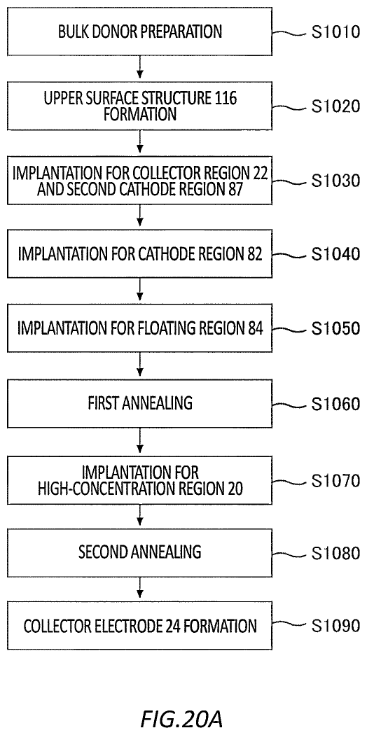

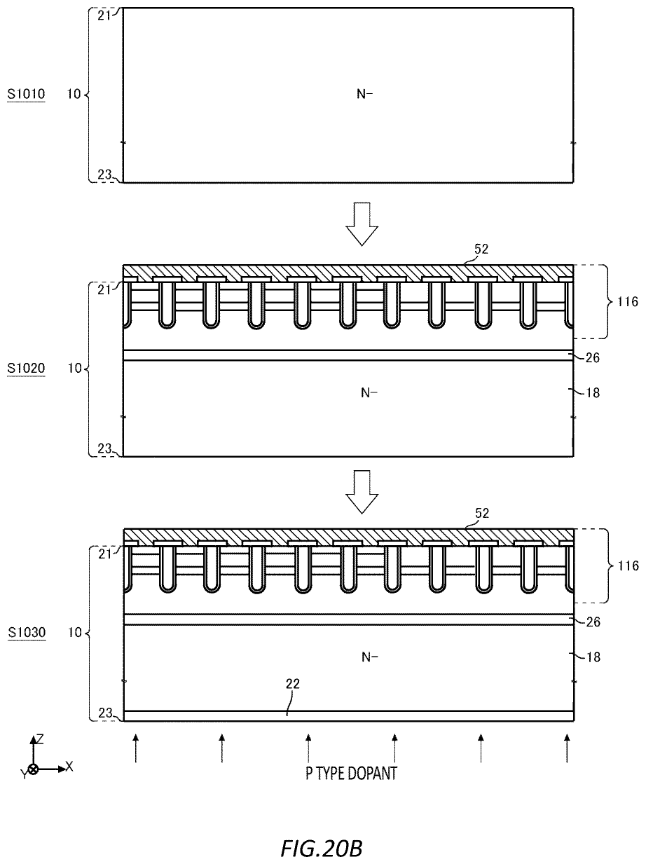

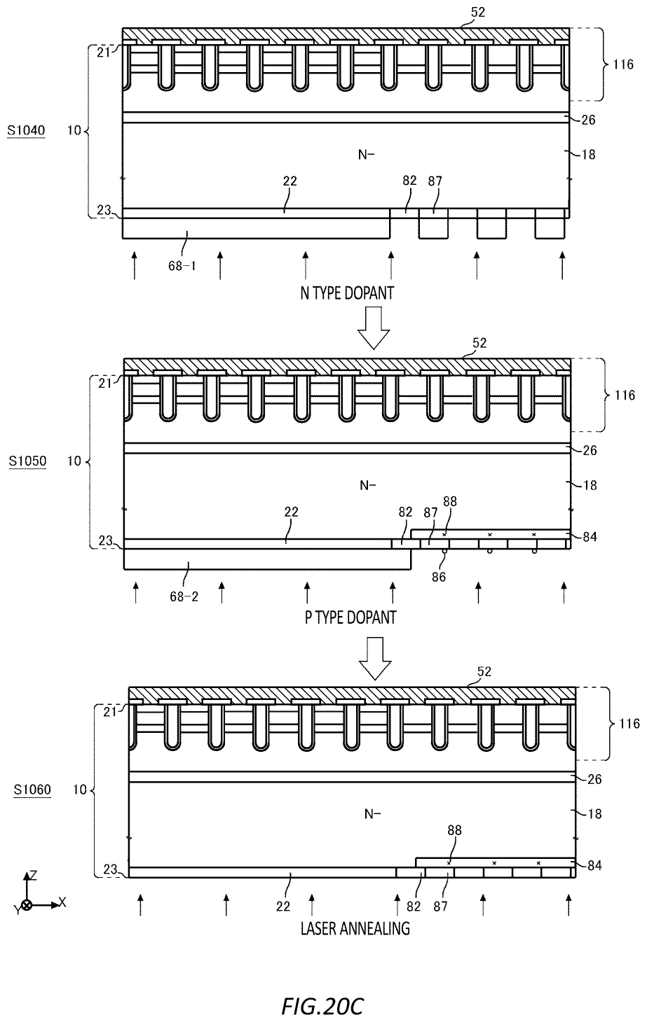

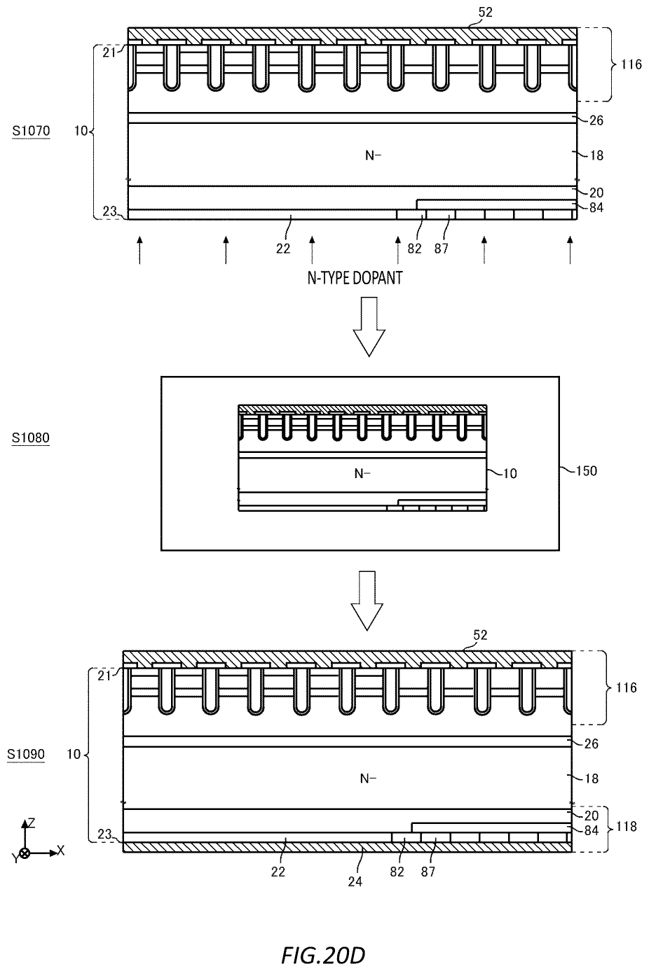

FIG. 20A is a flow diagram illustrating a manufacturing method of the semiconductor device 100A. The manufacturing method of the semiconductor device 100A includes a bulk wafer preparation step (S1010), an upper surface structure forming step (S1020), an implantation step for the collector region and the second cathode region (S1030), an implantation step for the cathode region (S1040), an implantation step for the floating region (S1050), a first annealing step (S1060), an implantation step for the high-concentration region (S1070), a second annealing step (S1080), and a collector electrode forming step (S1090). In the present embodiment, each step is performed in the order from those with smaller numbers following S.

FIG. 20B illustrates each step of S1010 to S1030 of the manufacturing method of the semiconductor device 100A. At S1010, a bulk wafer of an N− type is prepared as the semiconductor substrate 10. A bulk donor of an N type is distributed throughout the entire bulk wafer of the N− type. The bulk donor is a dopant donor substantially uniformly contained in an ingot during the manufacture of the ingot from which the semiconductor substrate 10 is made. The bulk donor of this example is a first element that is volatile. For example, the first element is antimony. In addition, the first element may be arsenic. By selecting these volatile elements as the bulk donor, the concentration of impurity elements can be adjusted through pressure control at the manufacturing step of the ingot. That is, resistivity can be adjusted to be uniform. Accordingly, yield of the bulk wafer that can be cut out from the ingot can be improved.

At S1020, an upper surface structure 116 is formed. The upper surface structure 116 includes a mesa portion 60, a mesa portion 61, a dummy trench portion 30, a gate trench portion 40, an interlayer dielectric film 38, and an emitter electrode 52. An emitter region 12, a base region 14, a contact region 15, and an accumulation region 16 may be included in the mesa portion 60. The base region 14, the contact region 15, and the accumulation region 16 may be included in the mesa portion 61. At S1020, a P type dopant for the base region 14 may be implanted into the upper surface 21 of the semiconductor substrate 10 of an N− type. In addition, an N type dopant for the second high-concentration region 26 may be implanted. The second high-concentration region 26 is a region that is formed on the upper surface 21 side of the semiconductor substrate 10 in the depth direction, and has a higher donor concentration than the drift region 18. In addition, each trench portion may be formed on the semiconductor substrate 10. In the step of forming the dummy conductive portion 34 and the gate conductive portion 44 of each trench portion, a polysilicon layer of an outer circumferential gate runner 130 may further be formed. The dopant included in the semiconductor substrate 10 may be accelerated by an implantation apparatus in an ionic state to be implanted into the semiconductor substrate 10. The semiconductor substrate 10 may be annealed appropriately.

At S1020, after each trench portion is formed, the N type dopant for the accumulation region 16, the N type dopant for the emitter region 12, and the P type dopant for the contact region 15 may be selectively and sequentially implanted. After these dopants are implanted, the semiconductor substrate 10 may be annealed appropriately. At S1020, after implantation and annealing of the dopants, an interlayer dielectric film 38 may be formed through CVD. By selectively removing the interlayer dielectric film 38 and a thermal oxide film on the upper surface 21 through etching, an aperture including a contact hole 54 may be formed. The thermal oxide film is an dielectric film provided on the upper surface 21 when forming the gate dielectric film 42 and the dummy dielectric film 32, for example. At S1020, the implantation order of each dopant may be changed appropriately.

At S1020, after the interlayer dielectric film 38 and the contact hole 54 are formed, the emitter electrode 52 may be deposited through sputtering. When depositing the emitter electrode 52 through sputtering, a metal layer of the outer circumferential gate runner 130 and a gate pad 164 may also be deposited. After these metal layers are deposited, the emitter electrode 52, the metal layer of the outer circumferential gate runner 130, and the gate pad may be patterned into a predetermined shape. At S1020, a step of forming a passivation layer including a predetermine aperture on top of the emitter electrode 52 or the like may be included.

At S1020, in order to form the emitter region 12, a second element with a lower mass number than the first element is implanted. The second element is arsenic, for example. In addition, in order to form the accumulation region 16, a third element with a lower mass number than the second element is implanted. The third element is phosphorous, for example. In addition, in order to form the second high-concentration region 26, a fourth element with a lower mass number than the third element is implanted. The fourth element is hydrogen, for example. The second high-concentration region 26 may be formed through hydrogen ion implantation from the upper surface 21 side of the semiconductor substrate 10.

In this manner, by using an element with a low mass number for a dopant for which the implantation position relative to the upper surface 21 of the semiconductor substrate 10 is deeper, improvement of manufacture efficiency and reduction of damage to the semiconductor substrate 10 (for example, silicon base) can be contemplated. In addition, respectively changing the element to be implanted into each layer enables easily analyzing which step had an issue when contamination or the like occurred. Accordingly, cost reduction can be contemplated in a comprehensive manner.

The semiconductor device 100A does not need to have all of the emitter region 12, the accumulation region 16, and the second high-concentration region 26. For example, the semiconductor device 100A may not include either or both of the accumulation region 16 or the second high-concentration region 26. In this case, the first element that constitutes the bulk wafer may be arsenic and the second element that constitutes the emitter region 12 may be phosphorous, for example. The second element is preferably lighter than the first element. That is, in this example, at least the bulk donor of the N type of the semiconductor substrate 10 is an element with a higher mass number than the donor to be locally implanted into the semiconductor substrate 10. The bulk donor may include a plurality of elements. Any of the plurality of elements of the bulk donor may be an element with the highest mass number among the donors included in the semiconductor substrate 10.

At S1030, the P type dopant is implanted into the entire lower surface 23 of the semiconductor substrate 10. At S1030, the dopant for forming the collector region 22 in the transistor portion 70 may be implanted. That is, at S1030, the P type dopant may be doped at a dose amount corresponding to the doping concentration of the collector region 22 in the semiconductor device 100A.

FIG. 20C illustrates each step of S1040 to S1060 of the manufacturing method of the semiconductor device 100A. At S1040, a mask 68-1 made of a photoresist material or the like is first formed in contact with the entire lower surface 23 of the semiconductor substrate 10. Subsequently, the mask 68-1 is left in a range corresponding to the collector region 22 in the XY plane. When the second cathode region 87 is formed in the diode portion 80, the mask 68-1 is also left in a range corresponding to the second cathode region 87. The mask 68-1 is remove from a range corresponding to the cathode region 82.

After patterning the mask 68-1, a dopant of an N type is implanted into the lower surface 23 of the semiconductor substrate 10. At S1040, a dopant for forming the cathode region 82 in the diode portion 80 may be implanted. That is, at S1040, the N type dopant may be doped at a dose amount corresponding to the doping concentration of the cathode region 82 in the semiconductor device 100A. At S1040 of this example, in order to form the cathode region 82, a fifth element with a lower mass number than the first element is implanted. The fifth element is phosphorous or arsenic, for example.

Since the P type dopant has been implanted into the entire lower surface 23 at S1030, a P type region is formed on the entire lower surface 23 before ion implantation at S1040. By S1040, the N type dopant is counter-doped in a range that is not provided with the mask 68-1, to form a region of the N type in said range. In a range that is provided with the mask 68-1, the N type dopant may not be implanted. After the doping, the mask 68-1 may be removed.

At S1050, a P type dopant for forming the floating region 84 is implanted. When the floating region 84 is not to be provided in the semiconductor device 100A, S1050 may be omitted. At S1050, the mask 68-2 is provided in a rage other than the range corresponding to the floating region 84 in the XY plane. The mask 68-2 is formed in a similar way as the mask 68-1, but is provided in a range different from that of the mask 68-1 in the XY plane.

After patterning the mask 68-2, the dopant of the P type is implanted into the lower surface 23 of the semiconductor substrate 10. At S1050, a dopant for forming the floating region 84 of a P type may be implanted. That is, at S1050, the P type dopant may be doped at a dose amount corresponding to the doping concentration of the floating region 84 in the semiconductor device 100A. The implantation depth range of the P type dopant at S1050 may be deeper than the implantation depth range of the N type dopant at S1040. After the doping, the mask 68-2 may be removed.

The floating region 84 is a region of a P type in an electrically floating state. The floating region 84 may be provided in the diode portion 80. The floating region 84 may be dispersively provided throughout the entire diode portion 80. Being in an electrically floating state refers to a state of essentially not being electrically connected to either the collector electrode 24 or the emitter electrode 52. By providing the floating region 84, implantation of electrons from the cathode region 82 can be suppressed. In this manner, carrier distribution in the depth direction of the semiconductor substrate 10 can be adjusted without providing a lifetime killer on the lower-surface 23 side of the semiconductor substrate 10. Thus, the cost for providing the lifetime control region can be reduced. In addition, leakage current caused by the lifetime control region can also be reduced.

As described above, at S1040 and S1050, for each of the mask 68-1 and the mask 68-2, a plurality of masking processes of forming, patterning, and removing the masks are performed. Thus, the later the implantation steps among the plurality of implantation steps of implanting dopant ions, the higher the possibility of generation or attachment of particles 86 to the lower surface 23 of the semiconductor substrate 10 becomes. This may lead to a possibility of defects 88 in the semiconductor substrate 10 or damages thereto due to the particles 86. Since defects 88 or damages that occurred in the cathode region 82 directly influence the electrical characteristics of the diode portion 80, the impact on the characteristics of the semiconductor device 100A is large. For example, when defects 88 or damages occur in the cathode region 82, junction leakage, withstand voltage failure, and reduction in switching characteristics may occur.

In the manufacturing method of this example, S1050 is performed after S1040. In this manner, compared to a case where S1040 is performed after S1050, the lower surface 23 while S1040 is being performed can be in a cleansed state with few particle 86 or the like. Therefore, the risk of defects 88 or damages occurring in the cathode region 82 at S1040 can be reduced. Therefore, electrical leakage and withstand voltage failure at the semiconductor device 100 can be reduced. In this manner, in the manufacturing method of this example, the non-defective rate of RC-IGBT can be improved.

In the manufacturing method of this example, S1030 is performed while the lower surface 23 is in a cleansed state, defects 88 or damages in the collector region 22 can be reduced. In this manner, electrical leakage and withstand voltage failure can also be reduced in the collector region 22. Note that, in this example, since S1050 is performed after S1030 and S1040, relatively more particles 86 may be generated at when S1050 is performed. Thus, relatively more defects 88 may be introduced into the floating region 84. However, compared to a case where defects 88 or damages are introduced into the cathode region 82, the defects 88 introduced into the floating region 84 has less influence on the diode portion 80. It is relatively easy to maintain the defects 88 introduced into the floating region 84 at a permissible extent.

At S1060, a vicinity of the lower surface 23 of the semiconductor substrate 10 is locally annealed by radiating laser light to the lower surface 23. The temperature of a region radiated by the laser light at S1060 is about 1000° C., as an example. The laser light may have higher energy than the band-gap energy of the semiconductor substrate 10. By S1060, the crystal defect that occurred due to dopant ion implantation can be recovered, and the implanted dopant can be activated.

FIG. 20D illustrates each step of S1070 to S1090 of the manufacturing method of the semiconductor device 100A. At S1060, a dopant for forming the high-concentration region 20 (that functions as a field stop region, for example) is implanted. At S1060 of this example, a sixth element with a lower mass number than the first element and the fifth element is implanted. The sixth element is hydrogen, for example. Hydrogen is implanted from the lower surface 23 to a predetermined depth range. Note that, hydrogen may be implanted into the semiconductor substrate 10 in a state of hydrogen ion (proton, as an example). Hydrogen ion may be implanted into the semiconductor substrate 10 in a multi-stage manner with different implantation energy, such that a plurality of concentration peaks are provided in the high-concentration region 20 in the Z axis direction. At S1060, the high-concentration region 20 described in FIG. 1 to FIG. 16 may be formed.

At S1080, the semiconductor substrate 10 is annealed. In this example, the semiconductor substrate 10 is placed in a heat treatment furnace 150, and the entire semiconductor substrate 10 is annealed at a temperature of about 400° C. By performing the annealing for forming the high-concentration region 20 separately from S1050, the annealing temperature can be changed. Thus, the N type dopant implanted at S1070 can be activated at a temperature different from that for the P type and N type dopants implanted at S1030 to S1050. For example, when hydrogen is implanted at S1070, hydrogen in the high-concentration region 20 can be activated at a temperature that is most suitable for activation of hydrogen at S1080.

By performing S1070 after S1060, compared to a case in which S1070 is performed before S1060, implantation accuracy of the dopant for the high-concentration region 20 can be improved. Note that, for lifetime control, a step of implanting impurity for forming a lifetime killer in the semiconductor substrate 10 and a step of performing third annealing to recover the defects that have been excessively formed may be included after S1080.

At S1090, the collector electrode 24 is formed. In this example, the collector electrode 24 that is in contact with the entire lower surface 23 is formed through sputtering. In this manner, the semiconductor device 100A is completed.

According to the semiconductor device 100A of this example, improvement in manufacture efficiency and reduction in damages to the semiconductor substrate 10 (silicon base) can be contemplated by using a light element for the element o be implanted into a deeper position form the lower-surface 23 side of the semiconductor substrate 10. In addition, respectively changing the element that constitute each layer enables easily analyzing which step had an issue when contamination or the like occurred. Particularly, in the semiconductor device 100A, since respective structure of the bulk wafer the upper surface 21 side and the lower-surface 23 side is used properly for different properties of the impurity (element) to create each n type region, variation in resistivity is effectively suppressed. Accordingly, cost reduction can be contemplated in a comprehensive manner.

The semiconductor device 100A as described above may not include either or both of the accumulation region 16 or the second high-concentration region 26. In this case, the second element that constitutes the emitter region 12 and the fifth element that forms the cathode region 82 are preferably different elements. That is, the emitter region 12, the drift region 18, the high-concentration region 20, and the cathode region 82 provided in the RC-IGBT of a field stop type may be respectively constituted with different elements as their major dopants. In this case the fifth element may have a lower mass number than the second element. In addition, in the depth direction (Z axis direction) of the semiconductor substrate 10, the length of the emitter region 12 may be shorter than the length of the cathode region 82. As an example, the second element is arsenic and the fifth element is phosphorous. In this manner, the effect described above can be obtained more effectively. Note that, the second element, the third element, the fourth element, the fifth element, and the sixth element may include the same element. For example, the third element and the fifth element may be the same element. In addition, the fourth element and the sixth element may be the same element. Note that, an element that constitutes the major dopant of the bulk wafer is preferably not used in subsequent ion implantation.

In an example, for the semiconductor device 100A, the semiconductor layer in contact with the upper surface 21 or the lower surface 23 of the semiconductor substrate 10 is constituted through ion implantation of phosphorous or arsenic. Being sandwiched by the semiconductor layers on the upper surface 21 side or semiconductor layers on the lower-surface 23 side, hydrogen ion implantation is performed on a center side of the semiconductor substrate 10 relative thereto. The bulk wafer is formed by causing antimony, which is heavier than these, to become a donor.

The sequence of performing each process describes by using FIG. 20A to FIG. 20D may not necessarily be in this order. For example, the dopant implantation for forming the cathode region 82 at S1040 may be performed after forming the upper surface structure 116 at S1020. For example, the dopant implantation for forming the collector region 22 at S1030 may be performed after the dopant implantation for forming the floating region 84 at S1050. Although, in FIG. 20A to FIG. 20D, the RC-IGBT form has been described, it can be applied to semiconductor device or the like of a diode or a MOSFET type. In this case, a “source” and a “drain” in a transistor such as MOSFET, for example, may also be included in the range of terms such as the “emitter” and the “collector” in the present specification.

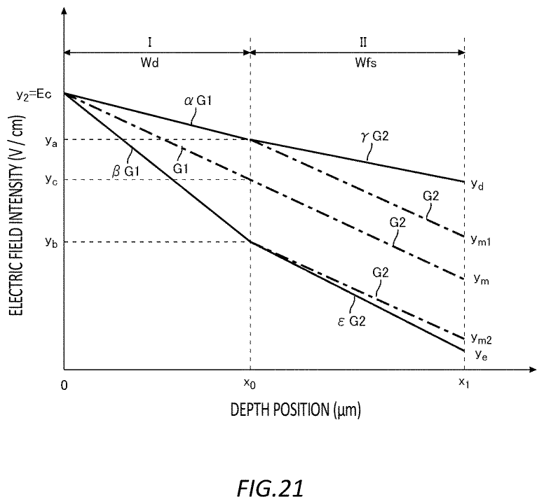

FIG. 21 illustrates a characteristic of breakdown voltage dispersion in the drift region 18 and the high-concentration region 20. The major dopant in the drift region 18 of this example is antimony and the major dopant in the high-concentration region 20 is hydrogen. The vertical axis in FIG. 21 represents the electric field intensity E (V/cm). The horizontal axis in FIG. 21 represents the depth position (μm) in the direction towards the lower surface 23, with the end on the upper surface 21 side of the drift region 18 as the reference position (position 0).

The breakdown voltage dispersion is defined as AV/Vc (where Vc is an average value of the breakdown voltage and AV is difference between a maximum value and a minimum value of the breakdown voltage). In order to simplify the calculation, the doping concentration is defined to be a constant concentration in each of the drift region 18 and the high-concentration region 20. An average concentration in each region may be used for said constant concentration. The voltage can be calculated by using Poisson equation and equation of E=−gradV through triangle approximation. The drift region 18 is defined as a region I, and the high-concentration region is defined as a region II. The breakdown voltage dispersion is separately calculated for the two regions.

### (Region I)

The gradient of the electric field intensity is defined as G1. The gradient G1 of this example is a negative value. It is assumed that, due to the variation in the dopant concentration in the drift region 18, the gradient G1 is increased to a value βG1 obtained by multiplying it by a coefficient β, or decreased to a value αG1 obtained by multiplying it by a coefficient α. The coefficient β of this example is greater than 1 and the coefficient α is less than 1. In the present specification, when the absolute value of the gradient of the electric field intensity is increased or decreased, it is referred to simply as the gradient of the electric field intensity being increased or decreased.

A maximum electric field intensity Ec at position 0 is defined as y₂. The boundary position between the drift region 18 and the high-concentration region 20 in the Z axis direction is defined as x₀. Among the electric field intensities at position x₀, the electric field intensity in a case where the gradient of the electric field intensity is G1 is defined as y_{c}, the electric field intensity in a case where the gradient of the electric field intensity is decreased to αG1 is defined as yₐ, and the electric field intensity in a case where the gradient of the electric field intensity is increased to βG1 is defined as y_{b}. The electric field intensity y_{c} indicates an average value of electric field intensity at position x₀. The gradient of each electric field intensity E in region I can be expressed by Expressions 1 to 3.

$$G 1 = ( {y}_{2} - {y}_{c} ) / ( - {x}_{0} ) \qquad ( 1 )$$

$$α G 1 = ( {y}_{2} - {y}_{a} ) / ( - {x}_{0} ) \qquad ( 2 )$$

$$β G 1 = ( {y}_{2} - {y}_{b} ) / ( - {x}_{0} ) \qquad ( 3 )$$

Expression 4 is obtained by deleting G1 from Expression 1 and Expression 2.

$${y}_{a} = ( 1 - α ) {y}_{2} + α {y}_{c} \qquad ( 4 )$$

Expression 5 is obtained by deleting G1 from Expression 1 and Expression 3.

$${y}_{b} = ( 1 - β ) {y}_{2} + β {y}_{c} \qquad ( 5 )$$

For the voltages in the region I, the average value is defined as VIc, the maximum value in a case of variation is defined as VImax, and the minimum value in a case of variation is defined as VImin. In FIG. 21, since the area of a region indicated by straight lines of respective electric field intensities becomes the voltage, each voltage can be expressed by Expression 6 to Expression 8.

$$VIc = 0.5 \times ( {y}_{c} + {y}_{2} ) {x}_{0} \qquad ( 6 )$$

$$VImax = 0.5 \times ( {y}_{a} + {y}_{2} ) {x}_{0} \qquad ( 7 )$$

$$VImin = 0.5 \times ( {y}_{b} + {y}_{2} ) {x}_{0} \qquad ( 8 )$$

As represented in Expression 9, y_{c} is X times of y₂.

$${y}_{c} = χ {y}_{2} ( 0 \leq χ \leq 1 ) \qquad ( 9 )$$

Expression 10 to Expression 12 are obtained by substituting Expressions 9, 4, and 5 for Expression 6 to 8, respectively, and deleting yₐ, y_{b}, and y_{c}.

$$VIc = 0.5 \times {x}_{0} \times ( χ + 1 ) {y}_{2} \qquad ( 10 )$$

$$VImax = 0.5 \times {x}_{0} \times {y}_{2} ( 2 - α + αχ ) \qquad ( 11 )$$

$$VImin = 0.5 \times {x}_{0} \times {y}_{2} ( 2 - β + βχ ) \qquad ( 12 )$$

### (Region II)

The gradient of the electric field intensity is defined as G2. It is assumed that, due to the variation in the dopant concentration in the high-concentration region 20, the gradient G2 is increased to a value εG2 obtained by multiplying it by a coefficient ε, or decreased to a value γG2 obtained by multiplying it by a coefficient γ. The coefficient ε of this example is greater than 1 and the coefficient γ is less than 1.

In the region II, it is assumed that a straight line indicating the electric field intensity in a case where the dopant concentration in the high-concentration region 20 is a minimum value is connected to a straight line indicating the electric field intensity in a case where the dopant concentration in the drift region 18 is a minimum value at a boundary position x₀ between the region I and the region II. Similarly, it is assumed a straight line indicating the electric field intensity in a case where the dopant concentration in the high-concentration region 20 is a maximum value is connected to a straight line indicating the electric field intensity in a case where the dopant concentration in the drift region 18 is a maximum value at a boundary position x₀ between the region I and the region II. That is, the straight line of the gradient αG1 indicating the electric field intensity of the region I and the straight line of the gradient γG2 indicating the electric field intensity of the region II are connected at the boundary x₀. In addition, the straight line of the gradient βG1 indicating the electric field intensity of the region I and the straight line of the gradient εG2 indicating the electric field intensity of the region II are connected at the boundary x₀.

(A Case where the Voltage in the Region I is a Maximum Value)

The voltage of the region I becomes a maximum value when the dopant concentration in the drift region 18 is varied to be a minimum value. The depth position of an end on the lower-surface 23 side of the high-concentration region 20 is defined as x₁. Among the electric field intensity at position x₁, the average value is defined as yₘ, and the electric field intensity in a case where the gradient of the electric field intensity is decreased to γG2 is defined as y_{d}. In addition, the electric field intensity at position x₁ in a case where the electric field intensity at the boundary x₀ is yₐ and the gradient of the electric field intensity in the region II is G2 is defined as yₘ₁. The gradient of each electric field intensity in the region II can be expressed by Expression 13 and Expression 14.

$$G 2 = ( {y}_{a} - {y}_{m 1} ) / ( - ( {x}_{1} - {x}_{0} ) \qquad ( 13 )$$

$$γ G 2 = ( {y}_{a} - {y}_{d} ) / ( - ( {x}_{1} - {x}_{0} ) ) \qquad ( 14 )$$

G2 is to be deleted from Expression 13 and Expression 14. Then, since yₐ−y_{c}=yₘ₁−yₘ, Expression 15 is obtained.

$${y}_{d} = {y}_{a} + γ ( {y}_{m} - {y}_{c} ) \qquad ( 15 )$$

(A Case where the Voltage in the Region I is a Minimum Value)

The voltage of the region I becomes a minimum value when the dopant concentration in the drift region 18 is varied to be a maximum value. Among the electric field intensity at position x₁, the average value is defined as yₘ, and the electric field intensity in a case where the gradient of the electric field intensity is increased to εG2 is defined as yₑ. In addition, the electric field intensity at position x₁ in a case where the electric field intensity at the boundary x₀ is y_{b} and the gradient of the electric field intensity in the region II is G2 is defined as yₘ₂. The gradient of each electric field intensity in the region II can be expressed by Expression 16 and Expression 17.

$$G 2 = ( {y}_{b} - {y}_{m 2} ) / ( - ( {x}_{1} - {x}_{0} ) ) \qquad ( 16 )$$

$$ε G 2 = ( {y}_{b} - {y}_{e} ) / ( - ( {x}_{1} - {x}_{0 )} ) \qquad ( 17 )$$

G2 is to be deleted from Expression 16 and Expression 17. Then, since y_{c}−y_{b}=yₘ−yₘ₂, Expression 18 is obtained.

$${y}_{e} = {y}_{b} + ε ( {y}_{m} - {y}_{c} ) \qquad ( 18 )$$

For the voltages in the region II, the average value is defined as VIIc, the maximum value in a case of variation is defined as VIImax, and the minimum value in a case of variation is defined as VIImin. In FIG. 21, since the area of a region indicated by straight lines of respective electric field intensities becomes the voltage, each voltage can be expressed by Expression 19 to Expression 21.

$$VIIc = 0.5 \times ( {y}_{m} + {y}_{c} ) ( {x}_{1} - {x}_{0} ) \qquad ( 19 )$$

$$VIImax = 0.5 \times ( {y}_{d} + {y}_{a} ) ( {x}_{1} - {x}_{0} ) \qquad ( 20 )$$

$$VIImin = 0.5 \times ( {y}_{e} + {y}_{d} ) ( {x}_{1} - {x}_{0} ) \qquad ( 21 )$$

As represented in Expression 22, yₘ is λ times of y_{c}.

$${y}_{m} = λ {y}_{c} ( 0 \leq λ \leq 1 ) \qquad ( 22 )$$

Expressions 23 to 25 can be obtained by substituting Expressions 16 to 18 for the expressions 19 to 21, respectively, by using Expressions 4, 5, 9, and 22, and deleting yₐ, y_{b}, y_{c}, y_{d}, yₑ, and yₘ.

$$VIIc = 0.5 ( {x}_{1} - {x}_{0} ) \times {y}_{2} ( λ + 1 ) χ \qquad ( 23 )$$

$$VIImax = 0.5 ( {x}_{1} - {x}_{0} ) \times {y}_{2} ( 2 + γ ( λ - 1 ) χ ) \qquad ( 24 )$$

$$VIImin = 0.5 ( {x}_{1} - {x}_{0} ) \times {y}_{2} ( 2 + ε ( λ - 1 ) χ ) \qquad ( 25 )$$

### (The Region I+Region II)

In the breakdown voltage of the regions I and II, the maximum value is defined as Vmax, the minimum value is defined as Vmin, and the average value is defined as Vc. In addition, assuming that x₁−x₀=xH, Expressions 26 to 28 can be obtained.

$$Vc = VIc + VIIc = 0.5 {y}_{2} [ {x}_{0} \times ( χ + 1 ) + xH \times ( λ + 1 ) χ ] \qquad ( 26 )$$

$$Vmax = Vimax + VIImax = 0.5 {y}_{2} [ {x}_{0} \times ( 2 - α + αχ ) + xH \times ( 2 + γ ( λ - 1 ) χ ] \qquad ( 27 )$$

$$Vmin = VImin + VIImin = 0.5 {y}_{2} [ {x}_{0} \times ( 2 - β + βχ ) + xH \times ( 2 + ε ( λ - 1 ) χ ] \qquad ( 28 )$$

The ratio of the thickness of the drift region 18 to the thickness x₁ of the sum of the drift region 18 and the high-concentration region 20 is defined as ζ. ζ=x₀/(x₀+xH). Expressions 29 to 31 can be obtained by using this (to delete xH from Expressions 26 to 28.

$$Vc = 0.5 {y}_{2} {x}_{0} [ χ + 1 + ( λ + 1 ) χ ( 1 - ζ ) / ζ ] \qquad ( 29 )$$

$$Vmax = 0.5 {y}_{2} {x}_{0} [ 2 - α + αχ + \{ 2 + γ ( λ - 1 ) χ \} ( 1 - ζ ) / ζ ] \qquad ( 30 )$$

$$Vmin = 0.5 {y}_{2} {x}_{0} [ 2 - β + βχ + \{ 2 + ε ( λ - 1 ) χ \} ( 1 - ζ ) / ζ ] \qquad ( 31 )$$

From the above, by assuming ΔV=Vmax−Vmin, the breakdown voltage dispersion ratio ΔV/Vc is expressed by Expression 32 indicated by a relationship of coefficients only.

$$Δ V / Vc = [ ( β - α ) ( 1 - χ ) + ( λ - 1 ) χ ( γ - ε ) ( 1 - ζ ) / ζ ] / [ χ + 1 + ( λ + 1 ) χ ( 1 - ζ ) / ζ ] \qquad ( 32 )$$

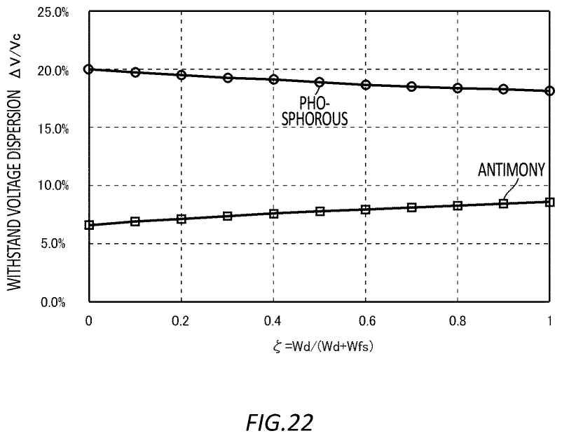

FIG. 22 is a graph illustrating the ratio relationship of the breakdown voltage dispersion to a coefficient ζ. In FIG. 22, an example in which the major dopant in the drift region 18 is phosphorous and an example in which it is antimony are illustrated. From the Poisson equation, the variation in the doping concentration becomes the variation in the gradient of the electric field intensity.

In this example, for the variation in the doping concentration of the drift region 18, it is 30% when the major dopant is phosphorous and 10% when the major dopant is antimony. The reasons are as below.
In a MCZ substrate, when the additive to become the dopant is phosphorous, the deviation of concentration in the ingot becomes 30% or more of the average value.
In a MCZ substrate, when the additive to become the dopant is antimony, the deviation of concentration in the ingot becomes approximately 10% of the average value.
That is, the deviation of dopant concentration in the ingot is smaller in the case of phosphorous than in the case of antimony.

When the major dopant is phosphorous, each coefficient in the drift region 18 described in FIG. 21 and the like was defined as α=0.7, β=1.3. When the major dopant is antimony, each coefficient in the drift region 18 was defined as α=0.9, β=1.1. The major dopant in the high-concentration region 20 of this example is hydrogen. Each coefficient in the high-concentration region 20 was defined as χ=0.5, γ=0.9, ε=1.1, λ=0.2. These coefficients are not limited to the above-described values. As an example, α may be in the range of 0.5 or more and 1 or less, β may be in the range of 1 or more and 1.5 or less, χ may be in the range of 0.1 or more and 0.9 or less, γ may be in the range of 0.5 or more and 1 or less, ε may be in the range of 1 or more and 1.5 or less, and λ may be in the range of 0.1 or more and 0.9 or less. When the major dopant in the drift region 18 is phosphorous, α may be 0.3 or more and 0. 7 or less, and β may be 1.3 or more and 3.0 or less. When the major dopant in the drift region 18 is antimony, α may be 0.7 or more and 0.99 or less, and β may be 1.01 or more and 1.3 or less.

From the graph of FIG. 22, when the major dopant in the drift region 18 is antimony, the breakdown voltage dispersion ratio becomes half or less as compared to a case of phosphorous. In addition, the more decreased the coefficient ζ, that is, the smaller the thickness ratio of the drift region 18, the smaller the breakdown voltage dispersion ratio becomes. This tendency is an effect of a different nature compared to a case where the major dopant is phosphorous/Since antimony has small concentration variation in the chemical concentration in the MCZ-type ingot, the variation in the antimony chemical concentration in the drift region 18 is also small in a plurality of semiconductor devices 100. It is considered that the effect of suppressing the breakdown voltage dispersion by the high-concentration region 20 is superimposed thereto. On the other hand, when the major dopant is phosphorous, the concentration variation in the chemical concentration in the MCZ-type ingot is large. It is considered that the drift region 18 actively contributes to the breakdown voltage dispersion, where the influence of its concentration variation is increased by the high-concentration region 20, and the breakdown voltage dispersion is increased by the decrease of the coefficient ζ.

When the major dopant in the drift region 18 is antimony, the thickness ratio ζ of the drift region 18 may be 0.1 or more, 0.2 or more, or 0.3 or more. It may be 0.5 or more. When the major dopant in the drift region 18 is antimony, the thickness ratio ζ of the drift region 18 may be 0.99 or less, 0.95 or less, 0.9 or less, 0.8 or less, or 0.7 or less.

When the major dopant in the high-concentration region 20 is phosphorous, the depth from the lower surface 23 of the high-concentration region 20 becomes extremely thin compared to a case where the major dopant is hydrogen. For example, the thickness from the lower surface 23 of the high-concentration region 20 becomes 10% or less of the thickness of the semiconductor substrate 10. In this case, the breakdown voltage dispersion ratio is calculated only for the region I, which may be defined as the breakdown voltage dispersion ratio of the semiconductor device 100.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

In the present specification and the drawings, aspects described in the following items are also disclosed.

### (Item 1)

A semiconductor device comprising a semiconductor substrate that has an upper surface and a lower surface has a drift region of a first conductivity type provided thereon, wherein
a major dopant in the drift region is antimony,
a ratio of a standard deviation of antimony chemical concentration in a first depth range in a depth direction of the semiconductor substrate to an average concentration of antimony chemical concentration in the first depth range is 0.2 or less, and
a thickness of the first depth range is 80% or more and 100% or less of a thickness of the semiconductor substrate.

### (Item 2)

The semiconductor device according to item 1, wherein
a ratio of a standard deviation of antimony chemical concentration in a second depth range in a depth direction of the drift region to an average concentration of antimony chemical concentration in the second depth range is 0.2 or less, and
a thickness of the second depth range is 50% or more and 100% or less of a thickness of the drift region.

### (Item 3)

A semiconductor device according to item 1, comprising a high-concentration region with a higher doping concentration than the drift region on the lower surface side of the drift region, wherein
a ratio of a thickness of the drift region to a total value of thicknesses in a depth direction of the drift region and the high-concentration region is 0.1 or more and 0.9 or less.

### (Item 4)

A semiconductor device comprising a semiconductor substrate that has an upper surface and a lower surface has a drift region of a first conductivity type provided thereon, comprising
a high-concentration region with a higher doping concentration than the drift region on the lower surface side of the drift region, wherein
a major dopant in the drift region is antimony, and
a ratio of a thickness of the drift region to a total value of thicknesses in a depth direction of the drift region and the high-concentration region is 0.1 or more and 0.99 or less.

### (Item 5)

A manufacturing method of a semiconductor device, comprising:
preparing a semiconductor substrate of a first conductivity type having an upper surface and a lower surface and including a first element that is volatile as a bulk donor;
performing ion implantation of a first light element with a lower mass number than the first element from the lower surface to form a field stop region of a first conductivity type; and
performing ion implantation of a second light element with a lower mass number than the first element from the lower surface side to form a cathode region of a first conductivity type in at least a part of the lower surface of the semiconductor substrate,
wherein each of the first element, the first light element, and the second light element is a different element, and the first light element has a lower mass number than the second light element.

### (Item 6)

The manufacturing method of the semiconductor device according to item 5, comprising:
performing ion implantation of a third light element with a lower mass number than the first element from the upper surface side to form an emitter region of a first conductivity type in at least a part of the upper surface of the semiconductor substrate,
wherein the third light element is an element that is different from the first element, the first light element, and the second light element, and the first light element and the second light element have lower mass number than the third light element.

What is claimed is:

1. A semiconductor device comprising a semiconductor substrate that has an upper surface and a lower surface, with a bulk donor distributed between the upper surface and the lower surface, and that has a drift region of a first conductivity type provided thereon, the semiconductor device comprising
a high-concentration region of a first conductivity type that is arranged between the drift region and the lower surface of the semiconductor substrate, includes a hydrogen donor, and has a carrier concentration that is higher than a bulk donor concentration, wherein
the high-concentration region has a first portion in which a hydrogen donor concentration obtained by subtracting a bulk donor concentration from a carrier concentration is 7×10¹³/cm³ or more and 1.5×10¹⁴/cm³ or less, and
a length of the first portion in a depth direction of the semiconductor substrate is 50% or more of a length of the high-concentration region.

2. The semiconductor device according to claim 1, wherein
the high-concentration region has a plurality of hydrogen donor concentration peaks in the depth direction,
the plurality of hydrogen donor concentration peaks include a shallowest donor concentration peak that is closest to the lower surface of the semiconductor substrate and a deepest donor concentration peak that is closest to the upper surface of the semiconductor substrate,
the high-concentration region has a second portion, which is a region that spans from the shallowest donor concentration peak to the deepest donor concentration peak, and
the length of the first portion in the depth direction of the semiconductor substrate is 50% or more of a length of the second portion.

3. The semiconductor device according to claim 1, wherein
the high-concentration region has a plurality of hydrogen donor concentration peaks in the depth direction,
the plurality of hydrogen donor concentration peaks include a deepest donor concentration peak that is closest to the upper surface of the semiconductor substrate,
the high-concentration region has a third portion in which regions with a hydrogen donor concentration of less than 7×10¹³/cm³ continue in the depth direction in a region that spans from the lower surface of the semiconductor substrate to the deepest donor concentration peak, and
a length of the third portion in the depth direction is 15 μm or less.

4. The semiconductor device according to claim 1, wherein
the high-concentration region has a plurality of hydrogen donor concentration peaks in the depth direction,
the plurality of hydrogen donor concentration peaks include a deepest donor concentration peak that is closest to the upper surface of the semiconductor substrate,
the high-concentration region has a third portion in which regions with a hydrogen donor concentration of less than 7×10¹³/cm³ continue in the depth direction in a region that spans from the lower surface of the semiconductor substrate to the deepest donor concentration peak, and
a length of the third portion in the depth direction of the semiconductor substrate is 20% or less of the length of the high-concentration region.

5. The semiconductor device according to claim 1, wherein
the high-concentration region has a plurality of hydrogen donor concentration peaks in the depth direction,
the plurality of hydrogen donor concentration peaks include a shallowest donor concentration peak that is closest to the lower surface of the semiconductor substrate and a deepest donor concentration peak that is closest to the upper surface of the semiconductor substrate, and
in the high-concentration region, a minimum value of a hydrogen donor concentration from the shallowest donor concentration peak to the deepest donor concentration peak is 7×10¹³/cm³ or more.

6. The semiconductor device according to claim 1, wherein
the high-concentration region has a plurality of hydrogen chemical concentration peaks in the depth direction, and
in each hydrogen chemical concentration peak, a length in the depth direction of a portion in which a hydrogen chemical concentration becomes 10% or more of a local maximum value is defined as a hydrogen peak width, and a sum of hydrogen peak widths, each being identical to the hydrogen peak width, of the plurality of hydrogen chemical concentration peaks is 30% or more of a length of the high-concentration region in the depth direction.

7. The semiconductor device according to claim 6, wherein the sum of the hydrogen peak widths is 50% or more of the length of the high-concentration region.

8. The semiconductor device according to claim 6, wherein
the plurality of hydrogen chemical concentration peaks include a same-concentration peak having a concentration that is 0.8 times or more and 1.2 times or less of a concentration of at least one hydrogen chemical concentration peak arranged adjacent thereto in the depth direction, and
three or more of the same-concentration peaks are arranged consecutively in the depth direction.

9. The semiconductor device according to claim 8, wherein
the high-concentration region has an upper region, which is a portion away from the lower surface of the semiconductor substrate in the depth direction by 20 μm or more, and
in the upper region, three or more of the same-concentration peaks are consecutively arranged in the depth direction.

10. The semiconductor device according to claim 9, wherein
a sum of the hydrogen peak widths in the upper region is 30% or more of a length of the upper region in the depth direction.

11. The semiconductor device according to claim 1, wherein
a hydrogen donor of the high-concentration region includes an interstitial donor, and
a concentration of the interstitial donor is 30% or more of a concentration of the hydrogen donor.

12. The semiconductor device according to claim 1, wherein
the high-concentration region has a plurality of hydrogen donor concentration peaks and one or more hydrogen donor concentration valley portions arranged between two hydrogen donor concentration peaks in the depth direction,
the plurality of hydrogen donor concentration peaks include a deepest donor concentration peak that is closest to the upper surface of the semiconductor substrate and a second deepest donor concentration peak that is second closest to the upper surface of the semiconductor substrate,
the one or more hydrogen donor concentration valley portions include a deepest donor concentration valley portion that is closest to the upper surface of the semiconductor substrate, and
a value obtained by dividing a hydrogen donor concentration at the second deepest donor concentration peak by a hydrogen donor concentration at the deepest donor concentration valley portion is 1.1 or more and 2.0 or less.

13. The semiconductor device according to claim 1, wherein
the high-concentration region has a plurality of hydrogen chemical concentration peaks in the depth direction,
the plurality of hydrogen chemical concentration peaks includes a third hydrogen concentration peak that is third closest to the lower surface of the semiconductor substrate,
the high-concentration region has a lower region that spans from the lower surface of the semiconductor substrate to the third hydrogen concentration peak and an upper region on the upper surface side of the semiconductor substrate relative to the third hydrogen concentration peak,
the lower region has, in the depth direction, a plurality of hydrogen donor concentration peaks and one or more hydrogen donor concentration valley portions arranged between two hydrogen donor concentration peaks,
the plurality of hydrogen donor concentration peaks of the lower region include a lower-side deepest donor concentration peak that is farthest from the lower surface of the semiconductor substrate,
the one or more hydrogen donor concentration valley portions of the lower region includes a lower-side deepest donor concentration valley portion that is farthest from the lower surface of the semiconductor substrate, and
a value a obtained by dividing a hydrogen donor concentration N₁ at the lower-side deepest donor concentration peak by a hydrogen donor concentration N₂ at the lower-side deepest donor concentration valley portion is 1.2 or more and 4.0 or less.

14. The semiconductor device according to claim 13, wherein
the upper region has, in the depth direction, a plurality of hydrogen donor concentration peaks and one or more hydrogen donor concentration valley portions arranged between two hydrogen donor concentration peaks,
the plurality of hydrogen donor concentration peaks of the upper region include a deepest donor concentration peak that is closest to the upper surface of the semiconductor substrate and a second deepest donor concentration peak that is second closest to the upper surface of the semiconductor substrate,
the one or more hydrogen donor concentration valley portions of the upper region include a deepest donor concentration valley portion that is closest to the upper surface of the semiconductor substrate, and
a value a/b obtained by dividing the value a by a value b obtained by dividing a hydrogen donor concentration n₁ at the second deepest donor concentration peak by a hydrogen donor concentration n₂ at the deepest donor concentration valley portion is greater than 0.5.

15. The semiconductor device according to claim 14, wherein
a hydrogen donor concentration n₁ at the second deepest donor concentration peak is 0.5 times or less of a hydrogen donor concentration N₁ at the lower-side deepest donor concentration peak.

16. The semiconductor device according to claim 1, wherein
the high-concentration region has a lower region on the lower surface side of the semiconductor substrate relative to a center of the high-concentration region in the depth direction and an upper region on the upper surface side of the semiconductor substrate relative to the center of the high-concentration region,
each of the lower region and the upper region has, in the depth direction, a plurality of hydrogen donor concentration peaks and one or more hydrogen donor concentration valley portions arranged between two hydrogen donor concentration peaks, and
a hydrogen donor concentration at at least one of the hydrogen donor concentration valley portions in the upper region is higher than a hydrogen donor concentration at at least one of the hydrogen donor concentration valley portions in the lower region.

17. The semiconductor device according to claim 1, wherein
the high-concentration region has an upper region which is a portion that is away from the lower surface of the semiconductor substrate in the depth direction by 20 μm or more,
the upper region has a plurality of hydrogen chemical concentration peaks in the depth direction, and
a sum of full width at half maximum of one or more hydrogen chemical concentration peaks, among the plurality of hydrogen chemical concentration peaks in the upper region, that have a hydrogen chemical concentration of 5×10¹⁵/cm³ or more is 20% or more and 90% or less of a length of the upper region in the depth direction.

18. The semiconductor device according to claim 1, wherein
the high-concentration region has an upper region which is a portion that is away from the lower surface of the semiconductor substrate in the depth direction by 20 μm or more,
the upper region has a plurality of hydrogen donor concentration peaks in the depth direction, and
a sum of full width at half maximum of one or more hydrogen donor concentration peaks, among the plurality of hydrogen donor concentration peaks in the upper region, that has a hydrogen donor concentration of 7×10¹³/cm³ or more is 30% or more of a length of the upper region in the depth direction.

19. The semiconductor device according to claim 1, wherein
the high-concentration region has an upper region which is a portion that is away from the lower surface of the semiconductor substrate in the depth direction by 20 μm or more, and
in the upper region, an integrated concentration obtained by integrating hydrogen donor concentrations in the depth direction is 8×10¹⁰/cm² or more and 2×10¹¹/cm² or less.

20. The semiconductor device according to claim 1, wherein
the high-concentration region has an upper region that is provided at at least a part in a range where a distance from the lower surface of the semiconductor substrate in the depth direction is 25% or more and 50% or less of a thickness of the semiconductor substrate,
the upper region has a plurality of hydrogen chemical concentration peaks in the depth direction, and
a sum of full width at half maximum of one or more hydrogen chemical concentration peaks, among the plurality of hydrogen chemical concentration peaks in the upper region, that has a hydrogen chemical concentration of 5×10¹⁵/cm³ or more is 20% or more and 90% or less of a length of the upper region in the depth direction.

21. The semiconductor device according to claim 1, wherein
the high-concentration region has an upper region that is provided at at least a part in a range where a distance from the lower surface of the semiconductor substrate in the depth direction is 25% or more and 50% or less of a thickness of the semiconductor substrate,
the upper region has a plurality of hydrogen donor concentration peaks in the depth direction, and
a sum of full width at half maximum of one or more hydrogen donor concentration peaks, among the plurality of hydrogen donor concentration peaks in the upper region, that has a hydrogen donor concentration of 7×10¹³/cm³ or more is 30% or more of a length of the upper region in the depth direction.

22. The semiconductor device according to claim 1, wherein
the high-concentration region has an upper region that is provided at at least a part in a range where a distance from the lower surface of the semiconductor substrate in the depth direction is 25% or more and 50% or less of a thickness of the semiconductor substrate, and
in the upper region, an integrated concentration obtained by integrating hydrogen donor concentrations in the depth direction is 8×10¹⁰/cm² or more and 2×10¹¹/cm² or less.

23. The semiconductor device according to claim 20, wherein
the upper region is provided on an entire range from 25% or more and 50% or less of a thickness of the semiconductor substrate.

24. The semiconductor device according to claim 1, wherein
a carbon concentration of the semiconductor substrate is 1×10¹³/cm³ or more and 5×10¹⁵/cm³ or less.

25. The semiconductor device according to claim 1, wherein
major dopant in the drift region is antimony,
a ratio of a standard deviation of antimony chemical concentration in a first depth range in a depth direction of the semiconductor substrate to an average concentration of antimony chemical concentration in the first depth range is 0.2 or less, and
a thickness of the first depth range is 50% or more and 100% or less of a thickness of the semiconductor substrate.

26. A semiconductor device comprising a semiconductor substrate that has an upper surface and a lower surface and has a drift region of a first conductivity type provided thereon, wherein
a major dopant in the drift region is antimony,
a ratio of a standard deviation of antimony chemical concentration in a first depth range in a depth direction of the semiconductor substrate to an average concentration of antimony chemical concentration in the first depth range is 0.2 or less, and
a thickness of the first depth range is 50% or more and 100% or less of a thickness of the semiconductor substrate.

27. The semiconductor device according to claim 26, wherein
a ratio of a standard deviation of antimony chemical concentration in a second depth range in a depth direction of the drift region to an average concentration of antimony chemical concentration in the second depth range is 0.2 or less, and
a thickness of the second depth range is 50% or more and 100% or less of a thickness of the drift region.

28. The semiconductor device according to claim 26, comprising
a high-concentration region on the lower surface side of the drift region, having a higher doping concentration than the drift region, wherein
a ratio of a thickness of the drift region to a total value of thicknesses of the drift region and the high-concentration region in the depth direction is 0.1 or more and 0.99 or less.

29. A semiconductor device comprising a semiconductor substrate that has an upper surface and a lower surface and has a drift region of a first conductivity type provided thereon, the semiconductor device comprising
a high-concentration region on the lower surface side of the drift region, having a higher doping concentration than the drift region,
a major dopant in the drift region is antimony, and
a ratio of a thickness of the drift region to a total value of thicknesses of the drift region and the high-concentration region in a depth direction is 0.1 or more and 0.99 or less.

30. The semiconductor device according to claim 1, wherein
in a depth direction of the semiconductor substrate, a length of the first portion is 70% or more of a length of the high-concentration region.

31. The semiconductor device according to claim 1, wherein
the high-concentration region has a plurality of hydrogen chemical concentration peaks in the depth direction,
the plurality of hydrogen chemical concentration peaks include a same-concentration peak having a concentration that is 0.8 times or more and 1.2 times or less of a concentration of at least one hydrogen chemical concentration peak arranged adjacent thereto in the depth direction, and
three or more of the same-concentration peaks are consecutively arranged in the depth direction.

32. The semiconductor device according to claim 13, wherein
a value a obtained by dividing a hydrogen donor concentration N₁ at the lower-side deepest donor concentration peak by a hydrogen donor concentration N₂ at the lower-side deepest donor concentration valley portion is 2.5 or more and 4.0 or less.

33. The semiconductor device according to claim 13, wherein
a value a obtained by dividing a hydrogen donor concentration N₁ at the lower-side deepest donor concentration peak by a hydrogen donor concentration N₂ at the lower-side deepest donor concentration valley portion is 1.2 or more and 3.0 or less.

34. The semiconductor device according to claim 13, wherein
a peak concentration of the third hydrogen concentration peak is greater than a peak concentration of at least one of the hydrogen chemical concentration peaks provided in the upper region.

35. The semiconductor device according to claim 14, wherein
a value a/b obtained by dividing the value a by a value b obtained by dividing a hydrogen donor concentration n₁ at the second deepest donor concentration peak by a hydrogen donor concentration n₂ at the deepest donor concentration valley portion is greater than one.

36. The semiconductor device according to claim 26 wherein
the antimony is distributed from the upper surface to the lower surface of the semiconductor substrate.

37. The semiconductor device according to claim 28, wherein
a ratio of a thickness of the drift region to a total value of thicknesses of the drift region and the high-concentration region in a depth direction is 0.1 or more and 0.8 or less.
